(19) United States
(12) Patent Application Publication
(10) Pub. No.: US 2026/0321542 A1
(43) Pub. Date: Oct. 15, 2026

(54) High Speed, Robust Multi-Actuator Impedance Matching Method

(71) Applicant: MKS Inc., Andover, MA (US)

(72) Inventors: Aaron Burry, Andover, MA (US); Aaron Radomski, Andover, MA (US); Zachary Law, Andover, MA (US); Vladimir Kozitsky, Andover, MA (US); Alexander Jurkov, Andover, MA (US)

(73) Assignee: MKS Inc., Andover, MA (US)

(21) Appl. No.: 19/179,648

(22) Filed: Apr. 15, 2025

(51) Int. Cl. H01J 37/32; H03H 7/38

(52) U.S. Cl. CPC H01J 37/32183; H03H 7/38; H01J 2237/334

(57) ABSTRACT

A controller for a power generator. The controller includes a power controller configured to generate a plurality of control signals to vary a respective plurality of actuators controlling a power output by the power generator to a load. The plurality of control signals is determined in accordance with a cost function that varies based on a plurality of parameters of the power output by the power generator.

### FIELD

The present disclosure relates to RF generator systems and to control of RF generators.

### BACKGROUND

Plasma processing is frequently used in semiconductor fabrication. In plasma processing, ions are accelerated by an electric field to etch material from or deposit material onto a surface of a substrate. In one basic implementation, the electric field is generated based on Radio Frequency (RF) or Direct Current (DC) power signals generated by a respective RF or DC generator of a power delivery system. The power signals generated by the generator must be precisely controlled to effectively execute plasma etching.

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions. One general aspect includes a controller for a power generator. The controller also includes a power controller configured to generate a plurality of control signals to vary a respective plurality of actuators controlling a power output by the power generator to a load. The plurality of control signals is determined in accordance with a cost function that varies based on a plurality of parameters of the power output by the power generator. Other embodiments of this aspect include corresponding computer systems, apparatus, and computer programs recorded on one or more computer storage devices, each configured to perform the actions of the methods.

Implementations may include one or more of the following features. The controller where the plurality of control signals is controlled in accordance with one of minimizing or maximizing the cost function. The plurality of parameters includes forward power, reverse power, current, voltage, power amplifier dissipation, power controller stability margins, estimated plasma stability, impedance, reflection coefficient, real or imaginary parts of the reflection coefficient, or magnitude of the square of the reflection coefficient. The cost function includes one of impedance, reflection coefficient, one or more of real or imaginary parts of the reflection coefficient, or magnitude of the square of the reflection coefficient. The plurality of actuators includes at least a plurality of frequency, load capacitance, tune capacitance, rail voltage, and drive voltage. The power controller is configured to apply an extremum seeking control approach to generate the plurality of control signals. The power controller is configured to at least one of: select a step size from a plurality of step sizes for at least one of the plurality of control signals and update the at least one of the plurality of control signals in accordance with the selected step size, determine a gradient of the cost function and determine updates to the plurality of control signals based on the gradient, or determine a best fit of a polynomial and determine updates to the plurality of control signals based on the polynomial. At least one of the plurality of control signals is updated at a first rate and another of the plurality of control signals is updated at a second rate, where the first rate is faster than the second rate, and a frequency and load capacitance is updated at the first rate, and a tune capacitance is updated at the second rate. Implementations of the described techniques may include hardware, a method or process, or computer software on a computer-accessible medium.

One general aspect includes a power generator system also including a power source, the power source generating an output power communicated to a load. The system also includes a matching network between the power source and the load, the matching network receiving the output power and providing an impedance match between the power source and the load, where the matching network includes a load capacitance and a tune capacitance. The system also includes a controller coupled to the power source and the matching network, the power controller configured to generate a plurality of control signals communicated to the power source and the matching network to vary a respective plurality of actuators controlling the power communicated to a load. The plurality of actuators includes frequency of the power source, load capacitance of the matching network, and tune capacitance of the matching network, and plurality of control signal control the respective plurality of actuators. The plurality of control signals is determined in accordance with a cost function that varies based on a plurality of parameters of the power output by the power generator. Other embodiments of this aspect include corresponding computer systems, apparatus, and computer programs recorded on one or more computer storage devices, each configured to perform the actions of the methods.

Implementations may include one or more of the following features. The power generator system where the plurality of control signals is controlled in accordance with one of minimizing or maximizing the cost function. The plurality of parameters includes forward power, reverse power, current, voltage, power amplifier dissipation, power controller stability margins, estimated plasma stability, impedance, reflection coefficient, real or imaginary parts of the reflection coefficient, or magnitude of the square of the reflection coefficient. The cost function includes one of impedance, reflection coefficient, one or more of real or imaginary parts of the reflection coefficient, or magnitude of the square of the reflection coefficient. The plurality of actuators further includes at least one of rail voltage and drive voltage. The power controller is configured to apply an extremum seeking control approach to generate the plurality of control signals. The power controller is configured to at least one of: select a step size from a plurality of step sizes for at least one of the plurality of control signals and update the at least one of the plurality of control signals in accordance with the selected step size, determine a gradient of the cost function and communicate updates to the plurality of control signals based on the gradient, and determine a best fit of a polynomial and communicate updates to the plurality of control signals based on the polynomial. At least one of the plurality of control signals is updated at a first rate and another of the plurality of control signals is updated at a second rate, where the first rate is faster than the second rate, and the frequency and load capacitance is updated at the first rate, and the tune capacitance is updated at the second rate. Implementations of the described techniques may include hardware, a method or process, or computer software on a computer-accessible medium.

One general aspect includes a non-transitory computer-readable medium storing instructions. The non-transitory computer-readable medium storing instructions also includes controlling a power source to generate an output power communicated to a load. The instructions also include controlling a matching network between the power source and the load, the matching network receiving the output power and providing an impedance match between the power source and the load, where the matching network includes a load capacitance and a tune capacitance. The instructions also include generating a plurality of control signals to control the power source and the matching network to vary a respective plurality of actuators of the power source and the matching network. The instructions also include the plurality of actuators include frequency of the power source, load capacitance of the matching network, and tune capacitance of the matching network. The instructions also include the plurality of control signals is determined in accordance with a cost function that varies based on a plurality of parameters of the output power. Other embodiments of this aspect include corresponding computer systems, apparatus, and computer programs recorded on one or more computer storage devices, each configured to perform the actions of the methods.

Implementations may include one or more of the following features. The non-transitory computer-readable medium storing instructions where the plurality of parameters includes forward power, reverse power, current, voltage, impedance, reflection coefficient, real or imaginary parts of the reflection coefficient, or magnitude of the square of the reflection coefficient. The non-transitory computer-readable medium storing instructions the instructions may include at least one of: selecting a step size from a plurality of step sizes for at least one of the plurality of control signals and update the at least one of the plurality of control signals in accordance with the selected step size, determining a gradient of the cost function and communicate updates to the plurality of control signals based on the gradient; or determining a best fit of a polynomial and communicate updates to the plurality of control signals based on the polynomial. Implementations of the described techniques may include hardware, a method or process, or computer software on a computer-accessible medium.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings.

FIG. 1 is a schematic block diagram of a power delivery system having multiple power supplies arranged according to various configurations of the present disclosure;

FIG. 2 shows waveforms of a time-varying signal and a pulse modulating the time-varying signal to describe a pulse mode of operation;

FIG. 3 shows waveforms of a carrier signal and a pulse modulating the carrier signal to describe a pulsed DC mode of operation;

FIG. 4 is a schematic block diagram of a power supply and matching network of a power delivery system arranged according to various configurations of the present disclosure;

FIG. 5 shows a contour plot of the square of the magnitude of a reflection coefficient that varies with respect to a frequency actuator and a load capacitance actuator and shows a tuning trajectory;

FIGS. 6A-6B show contour plots of respective real and imaginary parts of the reflection coefficient of FIG. 5 that vary with respect to respective adjustments of the load capacitance actuator and of the frequency actuator;

FIG. 7 shows time series plots of the square of the magnitude and real and imaginary parts of the reflection coefficient with respect to the frequency actuator and the load capacitance actuator of FIGS. 5, 6A, 6B;

FIG. 8 shows a Smith chart that corresponds to the time series plots of FIG. 7;

FIG. 9 shows time series plots of the square of the magnitude and real and imaginary parts of the reflection coefficient with respect to a frequency actuator and a load capacitance actuator where the adjustments fail to tune to a minimum reflected power solution;

FIG. 10 shows a Smith chart that corresponds to the time series plots of FIG. 9;

FIG. 11 shows time series plots of the square of the magnitude and real and imaginary parts of the reflection coefficient with respect to a frequency actuator and a load capacitance actuator, where the adjustments result in oscillation about a solution;

FIG. 12 shows a functional block diagram of an example control module arranged in accordance with various configurations;

FIG. 13 shows a flow chart of operation of a control system that determines adjustments of actuators based on a gradient of a cost function in accordance with the principles of the present disclosure;

FIG. 14 shows a flow chart of operation of a control system that determines adjustments of actuators using at least two different step sizes in accordance with the principles of the present disclosure;

FIG. 15 shows a flow chart of operation of a control system that determines adjustments of actuators based on a polynomial of a gradient of a cost function in accordance with the principals of the present disclosure;

FIG. 16 shows a flow chart of operation of a control system that adjusts a gradient of a cost function that determines adjustments of actuators in accordance with the principals of the present disclosure;

FIG. 17 shows a flow chart of operation of a control system having actuators that operate at different speeds and are sampled at different sampling rates in accordance with the principals of the present disclosure;

FIG. 18 shows contour plots of the square of the magnitude of a reflection coefficient that varies with respect to a frequency actuator and a load capacitance actuator determined using an extremum seeking control tuning approach and shows various tuning trajectories, each originating in a respective quadrant of the contour plots;

FIG. 19 shows contour plots of the square of the magnitude of a reflection coefficient that varies with respect to a frequency actuator and a load capacitance actuator and shows various tuning trajectories, each originating in a respective quadrant of the contour plots determined using a tuning approach of FIG. 13; and

FIG. 20 shows time series plots of the square of the magnitude and real and imaginary parts of the reflection coefficient with respect to a frequency actuator, a tune capacitance actuator, and a load capacitance actuator using a tuning approach of FIG. 17.

In the drawings, reference numbers may be reused to identify similar and/or identical elements.

### DETAILED DESCRIPTION

A power system may include a DC or RF power generator or DC or RF generator, collectively referred to as generator or generators, a matching network, and a load (such as a process chamber, a plasma chamber, or a reactor having a fixed or variable impedance). The generator generates a DC power signal or a sinusoidal, RF, or other time-varying signal, which is received by the matching network or impedance optimizing controller or circuit. The matching network or impedance optimizing controller or circuit transforms a load impedance to a characteristic impedance of a transmission line between the generator and the matching network. Impedance matching aids in maximizing an amount of power delivered to the load (“delivered power”) and minimizing an amount of power reflected back from the load to the generator (“reverse power” or “reflected power”). Delivered power may be maximized by minimizing reflected power when the input impedance of the matching network matches the characteristic impedance of the transmission line and generator.

In the power source or power supply field, there are typically two approaches to applying a power signal to the load. A first, more traditional approach is to apply a continuous voltage, current, or power signal to the load. In a continuous mode or continuous wave mode, a continuous voltage, current, or power signal is typically a constant DC, sinusoidal, or periodic time-varying signal, which may be a RF or other voltage, current, or power signal, which is output continuously by the power source to the load. In the continuous mode approach, the voltage, current, or power signal assumes a constant DC or sinusoidal output, and the amplitude of the power signal and/or frequency (of a RF power signal) can be varied in order to vary the output power applied to the load.

A second approach to applying the power signal to the load involves pulsing a voltage, current, or power signal, rather than applying a continuous voltage, current, or power signal to the load. In a pulse or pulsed mode of operation, a voltage, current, or power signal or carrier signal is modulated by a modulation signal in order to define an envelope for the modulated power signal. The voltage, current, or power signal may be, for example, a sinusoidal RF signal or other periodic or nonperiodic time-varying signal. Power delivered to the load is typically varied by varying the modulation signal. In a pulsed mode of operation of a pulsed DC signal, the voltage, current, or power signal may be a periodic or nonperiodic DC signal that alternates between at least a first amplitude and a second amplitude over one or more cycles and modulated by a modulation signal in order to define an envelope for the pulsed DC signal. In various configurations, a transition between the first amplitude and the second amplitude may include various shapes, including vertical slopes, nonvertical slopes, or combinations thereof, stair steps, and the like. Further the transition between the first amplitude and the second, or the second amplitude and the first amplitude, may be consistent or vary from cycle-to-cycle.

In one various power supply configuration, output voltage, current, or power applied to the load is determined using sensors that measure the forward and reflected voltage, current, or power signal. Either set of these signals is analyzed in a control loop. The analysis typically determines a parameter or a cost function that varies in accordance with a voltage, current, or power value and is used to adjust the output of the power supply in order to vary the voltage, current, or power applied to the load. In a power delivery system where the load is a process chamber or other nonlinear or time-varying load, the varying impedance of the load causes a corresponding varying of voltage, current, or power applied to the load and consequent varying of the parameter or cost function, as applied voltage, current, or power is in part a function of the impedance of the load.

In systems where fabrication of various devices relies upon introduction of voltage, current, or power to a load to control a fabrication process, voltage, current, or power is typically delivered in one of two configurations. In a first configuration, voltage, current, or power is capacitively coupled to the load. Such systems are referred to as capacitively coupled plasma (CCP) systems. In a second configuration, the voltage, current, or power is inductively coupled to the load. Such systems are typically referred to as inductively coupled plasma (ICP) systems. Coupling to the plasma can also be achieved via wave coupling at microwave frequencies. Such an approach typically uses Electron Cyclotron Resonance (ECR) or microwave sources. Helicon sources are another form of wave coupled sources and typically operate at frequencies similar to that of conventional ICP and CCP systems. In various configurations, the Helicon sources may operate at RF frequencies. Power delivery systems may include at least one bias power and/or a source power applied to one or a plurality of electrodes of the load. The source power typically generates a plasma and controls plasma density, and the bias power modulates ions in the formulation of the sheath. The bias and the source may share the same electrode or may use separate electrodes, in accordance with various design considerations.

When a power delivery system drives a time-varying or nonlinear load, such as a process chamber or plasma chamber, the power absorbed by the bulk plasma and plasma sheath results in a density of ions with a range of ion energy. One characteristic measure of ion energy is the ion energy distribution function (IEDF). The ion energy distribution function (IEDF) can be controlled with the bias power or voltage. One way of controlling the IEDF for a system in which multiple voltage, current, or power signals are applied to the load occurs by varying multiple voltage, current, or power signals that are related by at least one of amplitude, frequency, and phase. The related at least one of amplitude, frequency, and phase of multiple voltage, current, or power signals may also be related by a Fourier series and the associated coefficients. The frequencies between the multiple voltage, current, or power signals may be locked, and the relative phase between the multiple voltage, current, or signals may also be locked. Examples of such systems can be found with reference to U.S. Pat. No. 7,602,127, issued Oct. 13, 2009; U.S. Pat. No. 8,110,991, issued Feb. 7, 2012; and U.S. Pat. No. 8,395,322, issued Mar. 12, 2013, all entitled Phase and Frequency Control of a Radio Frequency Generator from an External Source, assigned to the assignee of the present application, and incorporated by reference herein.

Time varying or nonlinear loads may be present in various applications. In one application, plasma processing systems may also include components for plasma generation and control. One such component is a nonlinear load implemented as a process chamber, such as a plasma chamber or reactor. A typical plasma chamber or reactor utilized in plasma processing systems, such as by way of example, for thin-film manufacturing, can utilize a dual power system. One voltage, current, or power generator (the source) controls the generation of the plasma, and the other voltage, current, or power generator (the bias) controls ion energy. Examples of dual power systems include systems that are described in U.S. Pat. Nos. 7,602,127; 8,110,991; and 8,395,322, referenced above. The dual power system described in the above-referenced patents employs a closed-loop control system to adapt power supply operation for the purpose of controlling ion density and its corresponding ion energy distribution function (IEDF).

Multiple approaches exist for controlling a process chamber, such as may be used for generating plasmas. For example, in voltage, current, or power delivery systems, phase and frequency of multiple driving signals operating at the same or nearly the same frequency may be used to control plasma generation. For such driven plasma sources, the periodic waveform affecting plasma sheath dynamics and the corresponding ion energy are generally known and are controlled by the frequency of the periodic waveforms and the associated phase interaction. Another approach in voltage, current, or power delivery systems involves dual frequency control. That is, two frequency sources operating at different frequencies are used to power a plasma chamber to provide substantially independent control of ion and electron densities. In various configurations, the frequency may be a RF frequency.

Another approach utilizes wideband RF power sources to drive a plasma chamber. A wideband approach presents certain challenges. One challenge is coupling the power to the electrode. A second challenge is that the transfer function of the generated waveform to the actual sheath voltage for a desired IEDF must be formulated for a wide process space to support material surface interaction. In one responsive approach in an inductively coupled plasma system, controlling power applied to a source electrode controls the plasma density while controlling power applied to the bias electrode modulates ions to control the IEDF to provide etch rate and etch feature profile control. By using source electrode and bias electrode control, the etch rate and other various etch characteristics are controlled via the ion density and energy.

As integrated circuit and device fabrication continues to evolve, so do the power requirements for controlling the process for fabrication. For example, with memory device fabrication, the requirements for bias voltage, current, or power continue to increase. Increased voltage, current, or power generates higher and more energetic ions for increased directionality or anisotropic etch feature profiles and faster surface interaction, thereby increasing the etch rate and allowing higher aspect ratio features to be etched. In one nonlimiting example, in some voltage, current, or power delivery systems, increased ion energy is sometimes accompanied by a lower bias frequency requirement along with an increase in the power and number of bias power sources coupled to the plasma sheath created in the plasma chamber. The increased power at a lower bias frequency and the increased number of bias power sources results in intermodulation distortion (IMD) from sheath modulation. The IMD emissions can significantly reduce power delivered by the source where plasma generation occurs. U.S. Pat. No. 10,821,542, issued Nov. 3, 2020, entitled Pulse Synchronization by Monitoring Power in Another Frequency Band, assigned to the assignee of the present application, and incorporated by reference herein, describes a method of pulse synchronization by monitoring power in another frequency band. In the referenced U.S. patent application, the pulsing of a second RF generator is controlled in accordance with detecting at the second RF generator the pulsing of a first RF generator, thereby synchronizing pulsing between the two RF generators.

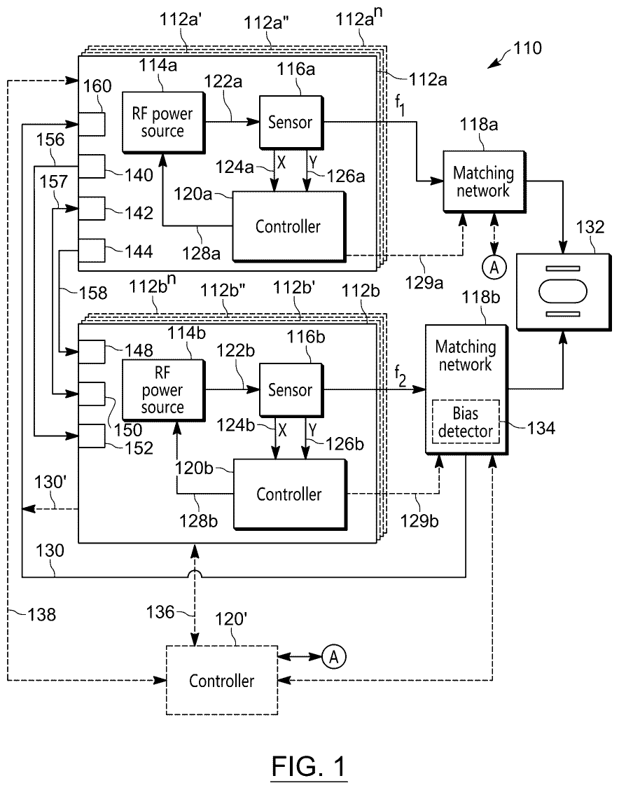

FIG. 1 depicts a RF generator or power supply system 110. Power supply system 110 includes a pair of radio frequency (RF) generators or power supplies 112a, 112b, matching networks 118a, 118b, and load 132, such as a nonlinear load, which may be a plasma chamber, plasma reactor, process chamber, and the like. In various configurations, generator 112a is referred to as a source generator or power supply, and matching network 118a is referred to as a source matching network. Further, in various configurations, one or both of voltage current, or power generators or power supplies 112a, 112b may output a continuous or pulsed time-varying voltage, current, or power signal or a continuous or pulsed DC voltage, current, or power signal. Also in various configurations, generator 112b is referred to as a bias generator or power supply, and matching network 118b is referred to as a bias matching network. It will be understood that components can be referenced individually or collectively using the reference number with or without a letter subscript or a prime symbol. In various configurations, one or both of matching networks 118a, 118b may be implemented as a RF blocking filter, rather than an impedance match, such as may be the case for a matching network receiving a pulsed DC or nonsinusoidal signal. In various other configurations, one or both of matching networks 118a, 118b may be omitted.

In various configurations, source generator 112a receives a control signal 130 from matching network 118b, generator 112b, or a control signal 130′ from bias generator 112b. Control signals 130 or 130′ represent an input signal to source generator 112a that indicates one or more operating characteristics or parameters of bias generator 112b. In various configurations, a synchronization bias detector 134 senses the signal output from matching network 118b to load 132 and outputs synchronization or trigger control signal 130 to source generator 112a. In various configurations, synchronization or trigger control signal 130′ may be output from bias generator 112b to source RF generator 112a, rather than trigger signal 130. A difference between trigger or synchronization signals 130, 130′ may result from the effect of matching network 118b, which can adjust the phase between the input signal to and output signal from matching network. Signals 130, 130′ include information about the operation of bias RF generator 112b that in various configurations enables predictive responsiveness to address periodic fluctuations in the impedance of plasma chamber or load 132 caused by the bias generator 112b. When control signals 130 or 130′ are absent, generators 112a, 112b operate autonomously.

Generators 112a, 112b include respective power sources or amplifiers 114a, 114b, sensors 116a, 116b, and processors, controllers, or control modules 120a, 120b. Power sources 114a, 114b generate respective voltage, current, or power signals 122a, 122b, various configurations of which are described above, output to respective sensors 116a, 116b. RF power signals 122a, 122b pass through sensors 116a, 116b and are provided to matching networks 118a, 118b as respective power signals f₁ and f₂. Sensors 116a, 116b output signals that vary in accordance with various parameters sensed from load 132. While sensors 116a, 116b, are shown within respective generators 112a, 112b, sensors 116a, 116b can be located externally to generators 112a, 112b. Such external sensing can occur at the output of the generator, at the input of an impedance matching device located between the generator and the load, or between the output of the impedance matching device (including within the impedance matching device) and the load.

Sensors 116a, 116b detect various operating parameters and output signals X and Y. Sensors 116a, 116b may include voltage, current, and/or directional coupler sensors. Sensors 116a, 116b may detect (i) voltage V and current I and/or (ii) forward power P_{FWD} output from respective power amplifiers 114a, 114b and/or RF generators 112a, 112b and reverse or reflected power P_{REV} received from respective matching networks 118a, 118b or load 132 connected to respective sensors 116a, 116b. The voltage V, current I, forward power P_{FWD}, and reverse power P_{REV} may be scaled, filtered, or scaled and filtered versions of the actual voltage, current, forward power, and reverse power associated with the respective power sources 114a, 114b. Sensors 116a, 116b may be analog or digital sensors or a combination thereof. In a digital implementation, the sensors 116a, 116b may include analog-to-digital (A/D) converters and signal sampling components with corresponding sampling rates. Signals X and Y can represent any of the voltage V and current I or forward (or source) power P_{FWD} reverse (or reflected) power P_{REV}.

Sensors 116a, 116b generate sensor signals X, Y, which are received by respective controllers or control modules 120a, 120b. Control modules 120a, 120b process the respective X, Y signals 124a, 126a and 124b, 126b and generate one or a plurality of feedforward or feedback control signals 128a, 128b to respective power sources 114a, 114b. Power sources 114a, 114b adjust voltage, current, or power signals 122a, 122b based on the received one or plurality feedback or feedforward control signal. In various configurations, control modules 120a, 120b may control matching networks 118a, 118b, respectively, via respective control signals 129a, 129b based on, for example, X, Y signals 124a, 126a and 124b, 126b. Control modules 120a, 120b may include one or more proportional-integral (PI), proportional-integral-derivative (PID), linear-quadratic-regulator (LQR) controllers or subsets thereof and/or direct digital synthesis (DDS) component(s) and/or any of the various components described below in connection with the modules.

In various configurations, control modules 120a, 120b may include functions, processes, processors, or submodules. Control signals 128a, 128b may be control or actuator drive signals and may communicate DC offset or rail voltage, voltage or current magnitude, frequency, and phase components, and the like. In various configurations, feedback control signals 128a, 128b can be used as inputs to one or multiple control loops. In various configurations, the multiple control loops can include a proportional-integral (PI), proportional-integral-derivative (PID) controllers, linear-quadratic-regulator (LQR) control loops, or subsets thereof, for RF drive, and for power supply rail voltage. In various configurations, control signals 128a, 128b can be used in one or both of a single-input-single-output (SISO) or multiple-input-multiple-output (MIMO) control scheme. An example of a MIMO control scheme can be found with reference to U.S. Pat. No. 10,546,724, issued on Jan. 28, 2020, entitled Pulsed Bidirectional Radio Frequency Source/Load, assigned to the assignee of the present application, and incorporated by reference herein. In other configurations, signals 128a, 128b can provide feedforward control as described in U.S. Pat. No. 10,049,857, issued Aug. 14, 2018, entitled Adaptive Periodic Waveform Controller, assigned to the assignee of the present application, and incorporated by reference herein.

In various configurations, power supply system 110 can include controller 120′. Controller 120′ may be disposed externally to either or both of generators 112a, 112b and may be referred to as external or common controller 120′. In various configurations, controller 120′ may implement one or a plurality of functions, processes, or algorithms described herein with respect to one or both of controllers 120a, 120b. Accordingly, controller 120′ communicates with respective generators 112a, 112b via a pair of respective links 136, 138 which enable exchange of data and control signals, as appropriate, between controller 120′ and generators 112a, 112b. For the various configurations, controllers 120a, 120b, 120′ can distributively and cooperatively provide analysis and control of generators 112a, 112b. In various other configurations, controller 120′ can provide control of generators 112a, 112b, eliminating the need for the respective local controllers 120a, 120b.

In various configurations, power source 114a, sensor 116a, controller 120a, and matching network 118a can be referred to as source power source 114a, source sensor 116a, source controller 120a, and source matching network 118a, respectively. Similarly in various configurations, power source 114b, sensor 116b, controller 120b, and matching network 118b can be referred to as bias power source 114b, bias sensor 116b, bias controller 120b, and bias matching network 118b, respectively. In various configurations and as described above, the source term refers to the generator or voltage, current, or power source that generates a plasma, and the bias term refers to the generator or voltage, current, or power source that tunes ion potential and the Ion Energy Distribution Function (IEDF) of the plasma. In various configurations, the source and bias power supplies operate at different frequencies or duty cycles. In various configurations, the source power supply operates at a higher frequency or duty cycle than the bias power supply. In various other configurations, the source and bias power supplies operate at the same frequencies or duty cycles or substantially the same frequencies or duty cycles.

According to various configurations, in addition to or by way of partial or total substitution to the synchronization signals described above with respect to control signals 130, 130′, source generator 112a and bias generator 112b include multiple ports to communicate with each other and with external devices. Source generator 112a includes pulse synchronization port 140, communication port 142, RF port 144, and control signal port 160. Bias generator 112b includes RF port 148, communication port 150, and pulse synchronization port 152. Pulse synchronization port 140 of source generator 112a communicates pulse synchronization signals via link 156 with pulse synchronization port 152 of bias generator 112b. Communication port 142 of source generator 112a and communication port 150 of bias generator 112b communicate data and information via a communication link 157. RF port 144 of source generator 112a communicates with RF port 148 via communication link 158. Control signal port 160 of source generator 112a receives one or both of control signals 130, 130', as described above. In various configurations, one or more of the ports described above may communicate with matching network 118 for communicating sensed or control signals, as may be described herein.

In various configurations, communication between pulse synchronization port 140 and pulse synchronization port 152 may be unidirectional or bidirectional between source generator 112a and bias generator 112b. In various configurations, one of source generator 112a and bias generator 112b communicate, by way of nonlimiting example, envelope pulse information to the other of bias generator 112b and source generator 112a. In various configurations, one or multiple communication links 156 link pulse synchronization port 140 and pulse synchronization port 152. In various configurations, communication between pulse synchronization port 140 and pulse synchronization port 152 may occur via analog or digital communication.

In various configurations, communication between communication port 142 of source generator 112a and communication port 150 of bias generator 112b may be unidirectional or bidirectional between source generator 112a and bias generator 112b. In various configurations, communication port 142 of source generator 112a and communication port 150 of bias generator 112b communicate, by way of nonlimiting example, data, information, or synchronization signals. In various configurations, one or multiple communication links 157 link communication port 142 and communication port 150 In various configurations, communication between communication port 142 and communication port 150 may occur via analog or digital communication.

In various configurations, communication between RF port 144 of source generator 112a and RF port 148 of bias generator 112b may be unidirectional or bidirectional between source generator 112a and bias generator 112b. In various configurations, RF port 144 of source generator 112b and RF port 148 of bias generator 112b communicate, by way of nonlimiting example, a signal indicating one or more of voltage, current, or power output by the respective generator. By way of nonlimiting example, time-varying RF signals, such as sinusoidal voltage, current, or power signals may be communicated. In various configurations, one or multiple communication links 158 link RF port 144 and RF port 148. In various configurations, communication between RF port 144 and RF port 148 may occur via analog or digital communication.

In various configurations, a control signal communicated via communications link 158 is substantially the same as the control signal controlling source generator 112a. In various other configurations, the control signal communicated via communications link 158 is the same as the control signal controlling source generator 112a, but is phase shifted within source generator 112a in accordance with a requested phase shift generated by bias generator 112b. Thus, in various configurations, source generator 112a and bias generator 112b are driven by substantially identical control signals or by substantially identical control signals phase shifted by a predetermined amount.

In various configurations, power supply system 110 may include multiple source generators 112a and multiple bias generators 112b. By way of nonlimiting example, a plurality of source generators 112a, 112a′, 112a″, . . . , 112aⁿ can be arranged to provide a plurality of output power signals to one or more source electrodes of load 132. Similarly, a plurality of bias generators 112b, 112b′, 112b″, . . . , 112bⁿ may provide a plurality of output power signals to a plurality of bias electrodes of load 132. When source generator 112a and bias generator 112b are configured to include a plurality of respective source generators or bias generators, each generator will output a separate signal to a corresponding plurality of matching networks 118a, 118b, configured to operate as described above, in a one-to-one correspondence. In various other configurations, there may not be a one-to-one correspondence between each generator and matching network. In various configurations, multiple source electrodes may refer to multiple electrodes that cooperate to define a composite source electrode. Similarly, multiple bias electrodes may refer to multiple connections to multiple electrodes that cooperate to define a composite bias electrode.

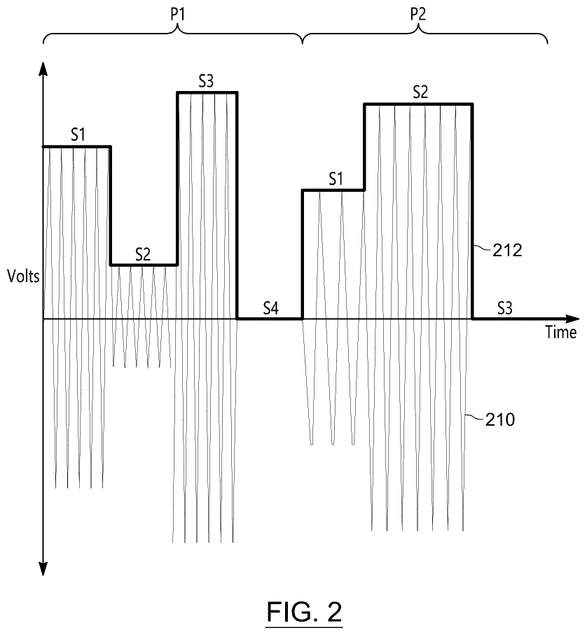

FIG. 2 shows a plot of voltage versus time to describe a pulse or pulsed mode of operation for delivering voltage, current, or power to a load, such as load 132 of FIG. 1. More particularly, FIG. 2 depicts signal or waveform 210, which, by way of nonlimiting example, is depicted as a sinusoidal signal or waveform. Waveform 210 may be referred to as a carrier waveform or carrier signal. Two multistate pulses P1, P2 of an envelope or pulse signal 212 having respective states S1-S4 and S1-S3 modulate waveform 210. As shown at states S1-S3 of P1 and S1-S2 of P2, when the pulses are ON, RF generator 112 outputs RF signal as waveform 210 having an amplitude defined by the pulse magnitude of each state. Conversely, during states S4 of P1 and S3 of P2, the pulses are OFF, and generator 112 does not output waveform 210. Pulses P1, P2 can repeat at a constant duty cycle or a variable duty cycle, and states S1-S4, S1-S3 of each respective pulse P1, P2 may have the same or varying amplitudes and widths.

In various configurations, signal or waveform 210 may include, in various nonlimiting examples, a sinusoidal signal or waveform, a nonsinusoidal signal or waveform, a square wave signal or waveform, a rectangular signal or waveform, triangular signal or waveform, a gaussian signal or waveform, or a piece-wise linear signal or waveform. In various other configurations, the signal or waveform may have a complex shape including a narrow pulse voltage peak followed by a ramp down in the voltage. In various other configurations, signal or waveform 210 may have an arbitrary shape variable from cycle to cycle. In other various configurations, signal or waveform 210 may be periodic or nonperiodic. Further, the frequency of waveform 210 may vary between or within states S1-S4, S1-S3 and between or within pulses P1, P2. Further, the frequency of waveform may vary between or within states S1-S4, S1-S3 and between or within pulses P1, P2.

In various embodiments, pulse signal 212 may be embodied as a square wave or rectangular wave as shown in FIG. 2. By way of nonlimiting example, pulse signal 212 may be trapezoidal, triangular, or gaussian in shape. Further yet, pulse signal 212 may have pulses P1, P2 that include multiple states S1, . . . , Sn of varying amplitude, duration, and shape. States S1, . . . , Sn may repeat within fixed or variable periods.

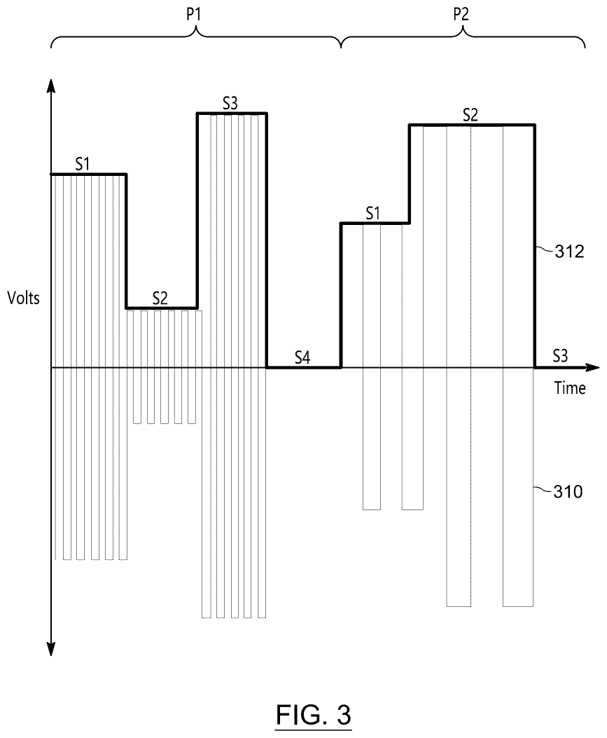

FIG. 3 depicts a plot of voltage versus time to describe an alternative pulse or pulsed mode of operation for delivering voltage, current, or power to a load, such as load 132 of FIG. 1. FIG. 3 depicts signal or waveform 310, which, by way of nonlimiting example, is depicted as a square wave signal or waveform. Waveform 310 may be referred to as a pulsed DC signal or waveform or a DC carrier signal or waveform. Two multistate pulses P1, P2 of an envelope or pulse signal 312 having respective states S1-S4 and S1-S3 modulate waveform 310. Waveform 310 is shown as a non-sinusoidal, periodic signal or waveform modulated by pulses P1 and P2. Waveform 310 may be a signal that pulses or oscillates between a first amplitude and a second amplitude over one or more cycles with various transitions therebetween.

At least one of the first and second amplitudes may vary over time in accordance with envelope or pulse signal 312. As shown at states S1-S3 of P1 and S1-S2 of P2, when the pulses are ON, RF generator 112 outputs modulated waveform 310 having an amplitude defined by the pulse magnitude of each state. Conversely, during states S4 of P1 and S3 of P2, the pulses are OFF, and generator 112 does not output waveform 310. Thus, modulating signal or waveform 310 (pulsed DC signal or waveform) with envelope or pulse signal 312 provides a pulse-within-a-pulse effect. Pulses P1, P2 can repeat at a constant duty cycle or a variable duty cycle, and states S1-S4, S1-S3 of each respective pulse P1, P2 may have the same or varying amplitudes and widths. In various configurations, while waveform 310 of FIG. 3 is shown as a square wave, waveform 310 need not be implemented as a conventional square wave. The first and second amplitudes of waveform 310 may be flat, sloping, or peaked, and the transitions between the first and second amplitudes may include linear slopes, stairsteps, other shapes, or combinations thereof. Further, states S1-S4, S1-S3 and pulses P1, P2 may have the shapes, frequencies, duty cycles, and repetition rates as described above with respect to FIG. 2.

In various configurations, the pulsed DC carrier signal of FIG. 3 may represent the output of a power source, such as a source power source or bias power source. In other various configurations, the pulsed DC carrier signal of FIG. 3 may represent the output of a matching network prior to application to a load. It should be recognized that the pulsed DC carrier signal of FIG. 3 may represent a shape of an output signal from a power source or a matching network.

In various configurations, pulse signal 212, 312 may be other than a square wave as shown in FIGS. 2, 3. Further, by way of nonlimiting example, envelope or pulse signal 212, 312 may be a single or multistate rectangular, trapezoidal, triangular, sawtooth, gaussian, or other shape that defines an envelope or modulating envelope of the underlying, modulated waveform 210. In various configurations, waveform 210, 310 may be referred to as a carrier signal and may occur or reoccur within fixed or variable periods or time periods. In various other configurations, waveform 210, 310 may vary in shape between each occurrence. Waveform 210, 310 may operate at frequencies that vary between states or within a state. In various other configurations, pulse signal 212, 312 may occur or reoccur within fixed or variable time periods and vary in shape between each occurrence. Further yet, pulses P1, P2 can have multiple states S1, . . . , Sn of varying amplitude, duration, and shape. States S1, . . . , Sn may repeat within fixed or variable periods and may include all or a portion of the various shapes described above.

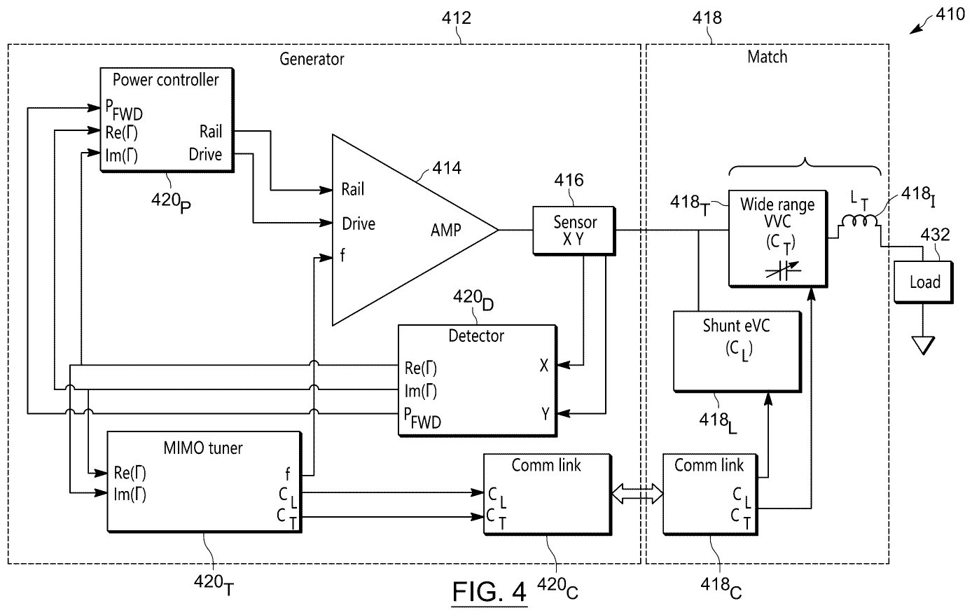

FIG. 4 shows a schematic block diagram of an expanded view of generator 412 and matching network 418 of power delivery system 410, such as may be seen with respect to generator 112a and matching network 118a; or generator 112b and matching network 118a; and controller 120,120′ of FIG. 1. Generator 412 includes RF power source or amplifier 414, sensor 416, and controller 420. As shown in FIG. 4, controller 420 is distributed across multiple processors or modules, including detector 420_{D}, tuner 420_{T}, power controller 420_{P}, and communication link 420_{C}. In various configurations, controller 420 may be a single controller, processor, or module including one or more of detector 420_{D}, tuner 420_{T}, power controller 420_{P}, and communication link 420_{C}. In various other configurations, controller 420 may be distributed across one or more controllers, processors, or modules, where each controller, processor, or module includes one or more of detector 420_{D}, tuner 420_{T}, power controller 420_{P}, and communication link 420_{C}. Further, while detector 420_{D} is represented as part of controller 420, detector 420_{D} may alternately be integral with sensor 416.

Generator 412 operates similarly as described above with respect to generators 112 of FIG. 1. Power source or amplifier 414 generates respective voltage, current, or power signals communicated to sensor 416. The respective voltage, current, or power signals pass through sensor 416 and are communicated to matching network 418. As described above, sensor 416 outputs signals X, Y that vary in accordance with various parameters sensed from load 432. Sensor 416 detects various operating parameters and outputs signals X and Y. Sensor 416 may include voltage, current, and/or directional coupler sensors. Sensor 416 may detect (i) voltage V and current I and/or (ii) forward power P_{FWD} output from power amplifiers 414 and/or generators 412 and reverse or reflected power P_{REV} from matching network 418 or load 432. The voltage V, current I, forward power P_{FWD}, and reverse power P_{REV} may be scaled, filtered, or scaled and filtered versions of the respective actual voltage, current, forward power, and reverse power associated with power source 414. Sensor 416 may be an analog or digital sensor or a combination thereof. In a digital implementation, sensor 416 includes analog-to-digital (A/D) converters and signal sampling components with corresponding sampling rates. Signals X and Y can represent any of the voltage V and current I or forward (or source) power P_{FWD} or reverse (or reflected) power P_{REV}.

In various configurations, sensor 416 generates sensor signals X, Y, which are communicated to detector 420_{D}. In one various configuration, detector 420_{D} processes respective X, Y signals and communicates one or more signals indicating forward power P_{FWD}, the real part of the reflection coefficient Re(Γ), and the imaginary part of the reflection coefficient Im(Γ). In various configurations, detector 420_{D} may communicate can output other values or characteristics indicative of operation of one or more components of power delivery system 410. Detector 420_{D} also communicates signals indicating forward power P_{FWD}, the real part of the reflection coefficient Re(Γ), and the imaginary part of the reflection coefficient Im(Γ) to tuner 420_{T} and power controller 420_{P}.

Power controller 420_{P} receives forward power P_{FWD}, real part of the reflection coefficient Re(Γ), and imaginary part of the reflection coefficient Im(Γ) signals and communicates one or more of a rail voltage and a drive signal to amplifier 414 to generate a desired output voltage, current, or power. Tuner 420_{T} receives the real part of the reflection coefficient Re(Γ) and imaginary part of the reflection coefficient Im(Γ) signals and communicates one or more of a frequency f command signal to amplifier 414 and respective load capacitance C_{L} command signal and tune capacitance C_{T} command signal to matching network 418. Load capacitance C_{L} and tune capacitance C_{T} command signals communicated to matching network 418 are communicated through communication link 420_{C} of generator 412 and communication link 418_{C} of matching network 418. In various configurations, generator 412 and matching network 418 may be either individual units or integrated into a single unit. Further, as mentioned above, sensor 416 can be located at the input of matching network 418 or between the output of matching network 418 and load 432. Further, in various configurations, sensor 416 may be integrated with generator 412 or matching network 418 or be a separate unit from either.

In various configurations, tuner 420_{T} is implemented as a multiple-input, multiple-output (MIMO) tuner. Tuner 420_{T} receives multiple inputs, such as forward power P_{FWD}, real part of the reflection coefficient Re(Γ), and imaginary part of the reflection coefficient Im(Γ) signals, and generates multiple outputs, such as frequency f, load capacitance C_{L} and tune capacitance C_{T} command signals. Power controller 420_{P} and tuner 420_{T} cooperate to effect MIMO control to adjust one or more of voltage, current, or power signals based on one or plurality feedback or feedforward control signals. In various configurations, tuner 420_{T} controls impedance by generating a command signal to adjust frequency f of the signal communicated from power source 414, and by communicating respective command signals to control load capacitance C_{L} and tune capacitance C_{T} of matching network 418.

Matching network 418 includes components for varying an impedance at the output of generator 412 to optimize power delivery to load 432. Matching network 418 includes shunt or load capacitance C_{L} 418_{L} arranged between an input to matching network 418 in parallel with load 432, and tune capacitance C_{T} 418_{T} in series between the input to matching network 418 and load 432. In various configurations, shunt or load capacitance C_{L} 418_{L} is implemented as an electronically variable capacitance (eVC) that receives load capacitance C_{L} command signal from communication link 418_{C}. In various configurations, electronically variable capacitance (eVC) is controlled by a phase and/or duty cycle signal that controls phased switching, thereby varying a resistive portion of matching network 418. An example of a phased switched matching network can be found with respect to U.S. Pat. No. 9,755,576; issued Sep. 5, 2017, entitled Tunable Matching Network with Phase-Switched Elements; and incorporated by reference herein. In a phased switched implementation, load capacitance C_{L} command signal defines a phase and/or duty cycle of operation of the phased switched components. In other configurations, the electronically variable capacitance (eVC) is implemented using a combined coarse tuning and fine tuning network. An example of a combined coarse tuning and fine tuning network can be found with respect to U.S. Pat. No. 10,229,816; issued Mar. 12, 2019; entitled Solid-State Impedance Matching Systems Including a Hybrid Tuning Network with a Switchable Coarse Tuning Network and a Varactor Fine Tuning Network, assigned to the assignee of the present application, and incorporated by reference herein. Of particular relevance to the present disclosure is that load capacitance C_{L} of matching network 418 can be varied at a relatively high rate of speed, thereby varying the resistive portion of matching network 418 at a relatively high rate of speed. Thus, the shunt or load capacitance C_{L} command signal controls components of shunt or load capacitance C_{L} to vary the resistive portion of matching network 418. In various configurations, the load capacitance C_{L} command signal may be comprised of multiple control signals. Further, in various configurations, MIMO tuner 420_{T} may communicate load capacitance C_{L} and tune capacitance C_{T} command signals directly to one or both of respective shunt or load capacitance C_{L} 418_{L} and tune capacitance C_{T} 418_{T}.

Matching network 418 also includes tune capacitance (C_{T}) 418_{T} arranged in series between an input to the matching network 418 and load 432. In various configurations, tune capacitance C_{T} 418_{T} is implemented as vacuum variable capacitance (VVC) and receives tune capacitance C_{T} command signal that defines a position of displaceable components of vacuum variable capacitance (VVC) from communication link 418_{C} to control tune capacitance C_{T}. Tune capacitance C_{T} 418_{T} connects to tune inductor 418_{I} in series between tune capacitance C_{T} 418_{T} and load 432. Tune capacitance C_{T} 418_{T} and tune inductor 418_{I} cooperate to form a resonant tank circuit. In a typical configuration, the VVC of the capacitance C_{T} 418_{T} is relatively slow relative to changes in impedance in power delivery system 410 and relative to the eVC of load capacitance C_{L} 418_{L}. By varying the frequency f output by power source or amplifier 414, however, a resonant condition can be achieved with tune capacitance C_{T} 418_{T} and tune inductor 418_{I} to improve the impedance match between generator 412 and load 432 to provide frequency impedance tuning.

In conventional implementations, each impedance actuator, such as frequency f, load capacitance C_{L}, and tune capacitance C_{T}, is controlled independently with separate feedback servo control loops to adjust the actuator position and reduce an error signal. For frequency f actuator, the error signal is typically a rotated version of the imaginary part of the reflection coefficient, which defines a reactive portion of matching network 418. Tune capacitance C_{T} actuator can be varied to increase the reactive tuning range of the frequency f actuator. For load capacitance C_{L} actuator, the error signal is typically the real part of the reflection coefficient Re(Γ), which defines a resistive portion of matching network 418. The separate, independent control loops of the servo controllers can sometimes conflict because each actuator affects at least some portion of the error signal of other control loop or loops.

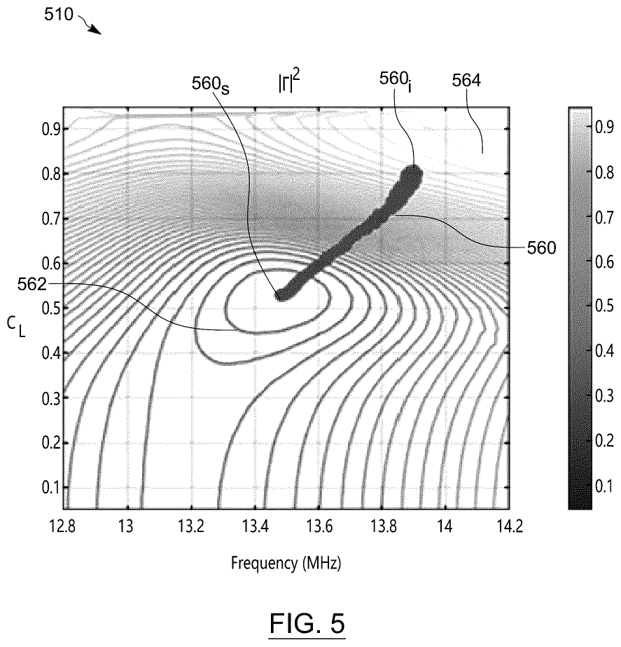

An example control adjustment is shown in FIG. 5 in contour plot 510. Contour plot 510 shows frequency f on the x-axis, load capacitance C_{L} on the y-axis, and contour lines, where each contour line indicates a constant of a parameter as frequency f and load capacitance C_{L} vary. Frequency f and load capacitance C_{L} represent the frequency f and load capacitance C_{L} resulting from varying respective control actuators. In the various configuration of FIG. 5, the parameter indicated by contour lines is the square of the magnitude of the reflection coefficient G_{mag}²=|Γ|. In various other configurations, the parameter can be one or more of impedance Z, reflection coefficient Γ, forward power, reverse power, current, and voltage. The square of the magnitude of the reflection coefficient G_{mag}²=|Γ| can vary between 0, indicating a preferred matching condition, and 1, indicating a least desirable matching condition. By way of non-limiting example, contour line 562 indicates a preferred region of operation, approaching G_{mag}²=0, where G_{mag}²≅0.049) frequency f and load capacitance C_{L}, indicating a generally preferred impedance match. Further by way of non-limiting example, contour line 564 indicates a generally least preferred region of operation, approaching G_{mag}²=1(G_{mag}²≅0.923), for frequency f and load capacitance C_{L}, indicating a generally least preferred impedance match. In FIG. 5, the contour lines between contour line 564 and contour line 562 generally indicate a decrease in G_{mag}² when transitioning from one contour line to an adjacent contour line in the direction of contour line 564. The distance or separation between adjacent contour lines generally indicates a slope of the gradient between the adjacent contour lines. Contour lines that are closely spaced indicate a relatively steep gradient between the parameter indicated by the contour lines, and contour lines that are spaced further apart indicate a generally less steep or flat gradient between the parameter indicated by the contour lines.

Contour plot 510 also includes trajectory 560 indicating a change in the parameter G_{mag}²) indicated by the contour lines as frequency f and load capacitance C_{L} vary. By way of non-limiting example, trajectory 560 has a starting or initial condition 560ᵢ (G_{mag}²≅0.877) and an end or solution 560ₛ (G_{mag}²≅0.49). By way of non-limiting example, as frequency f changes from approximately 13.90 MHz to 13.45 MHz and load capacitance C_{L} changes from approximately 0.80 to 0.51, G_{mag}² approaches 0, indicating a generally desirable impedance match. Put another way, both frequency f, controlled by the output of power source or amplifier 414 of FIG. 4, and load capacitance C_{L}, controlled by tuner 420_{T} to vary the electronically variable capacitance (eVC) of shunt or load capacitance C_{L} 418_{L} of FIG. 4, are controlled within the same control loop to achieve an impedance match. As will be described below, present impedance tuning systems are limited to tuning a single parameter and do not provide the MIMO tuning shown in FIG. 5.

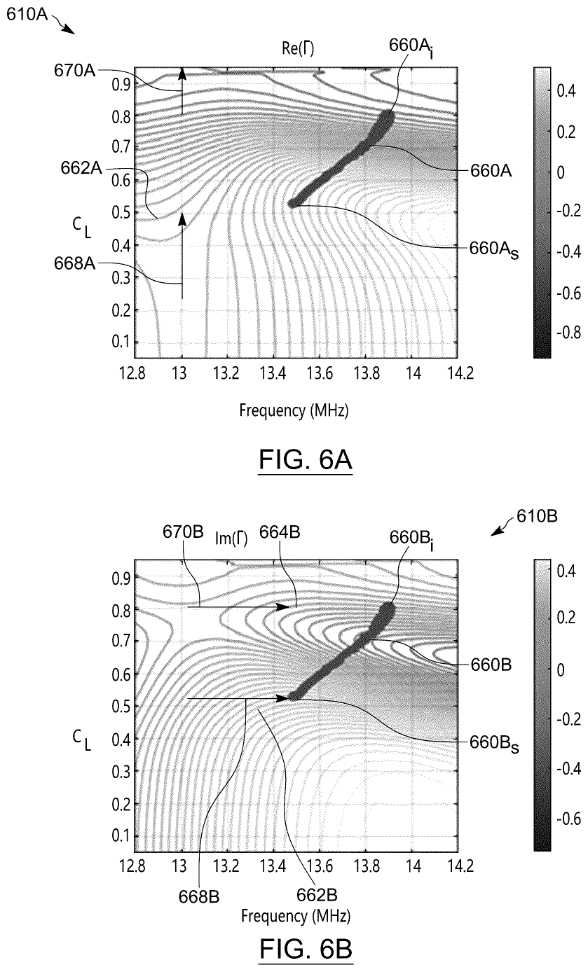

FIGS. 6A, 6B are contour plots 610A, 610B showing example outcomes when using separate servo controllers to control, by way of nonlimiting example, frequency f and load capacitance C_{L}, as is presently done in conventional control systems. FIG. 6A shows a contour plot of frequency f, load capacitance C_{L}, and contour lines, where each contour line indicates a real part of the reflection coefficient Re(Γ). FIG. 6A also shows trajectory 660A indicating a change in the parameter or cost function and having starting or initial condition 660Aᵢ(Re(Γ)≅−0.816) and end or solution 660Aₛ(Re(Γ)≅0.024). Trajectory 660A indicates a trajectory using the MIMO approach of the present disclosure controlling frequency f and load capacitance C_{L} in one control loop to reach a solution. FIG. 6B shows a contour plot of frequency f, load capacitance C_{L}, and contour lines, where each contour line indicates an imaginary part of the reflection coefficient Im(Γ). FIG. 6B also shown trajectory 660B indicating a change in the parameter or cost function and having starting or initial condition 660Bᵢ(Im(Γ)≅−0.413) and end or solution 660Bₛ(Im(Γ)≅−0.001). Trajectory 660B indicates a trajectory using the MIMO approach of the present disclosure controlling frequency f and load capacitance C_{L} and one control loop to reach a solution. In FIGS. 6A, 6B, the contour lines between respective initial conditions 660Aᵢ, 660Bᵢ and end or solutions 660Aₛ, 660Bₛ generally indicate a decrease in respective Re(Γ), Im(Γ) when transitioning from one contour line to an adjacent contour line in the direction of end or solutions 660Aₛ, 660Bₛ.

FIG. 6A includes two additional trajectories 668A, 670A to indicate behavior of a system configured to adjust only one of frequency f and load capacitance C_{L} in a single control loop. In the control loop represented by FIG. 6A, frequency f remains fixed (at approximately 13 MHz) while load capacitance C_{L} is adjusted. In a servo control approach, each control servo moves its actuator in the direction defined by the sign of its error signal. By way of non-limiting example, a negative error signal for Re(Γ) increases its corresponding load capacitance C_{L} actuator. Trajectory 668A of FIG. 6A represents a trajectory that reaches a solution approximately at contour line 662A (Re(Γ)≅−0.312), where Re(Γ) approaches zero, while trajectory 670A represents a trajectory that fails to reach a solution. With reference to trajectory 668A, as frequency f remains fixed, load capacitance C_{L} is adjusted from approximately 0.25 to 0.50, which reaches a solution at approximately 0.50 at contour line 662A. With reference to trajectory 670A, for a different initial condition, such as frequency f=13.0 MHz, and load capacitance C_{L}=0.8, trajectory 670A fails to reach a solution. As frequency f remains fixed, load capacitance C_{L} is adjusted from approximately 0.80 to the upper boundary of contour plot 610B because the sign of the error for load capacitance C_{L} remains negative, driving the actuator in a positive direction. The load capacitance C_{L} actuator is pinned at the maximum position, and the servo control fails to tune. Conventional tuning algorithms respond to this condition by rotating the feedback vector so that it points in the direction of the solution. Rotating the feedback vector, however, is difficult in practice due to the nonlinear nature of the plasma load.

FIG. 6B includes two additional trajectories 668B, 670B to indicate behavior of a system configured to adjust only one of frequency f and load capacitance C_{L} in a single control loop. In the control loop represented by FIG. 6B, frequency f is adjusted while load capacitance C_{L} remains fixed. Trajectory 668B of FIG. 6A represents a trajectory transitioning from Im(Γ)≅−0.237 to Im(Γ)≅−0.001 that reaches a solution approximately at contour line 662B, where Im(Γ) approaches zero, while trajectory 670B represents a trajectory that fails to reach a solution transitioning from Im(Γ)≅−0.354 to Im(Γ)≅−0.413. With reference to trajectory 668B, as load capacitance C_{L} remains fixed at approximately 0.5, frequency f is adjusted from approximately 13.0 MHz to 13.5 MHz, which reaches a solution at contour line 662B Im(Γ)≅−0.001. With reference to trajectory 670B starting at a different initial condition than for trajectory 668B, as load capacitance C_{L} remains fixed at approximately 0.8, frequency f is adjusted from approximately 13.1 MHz to 13.5 MHz. At load capacitance C_{L} of approximately 0.8, the frequency adjustment to 13.5 MHz yields a relatively high imaginary part of the reflection coefficient Im(Γ) at contour line 664B Im(Γ)≅−0.413. Thus, the different initial condition affects convergence in conventional servo tuning approaches.

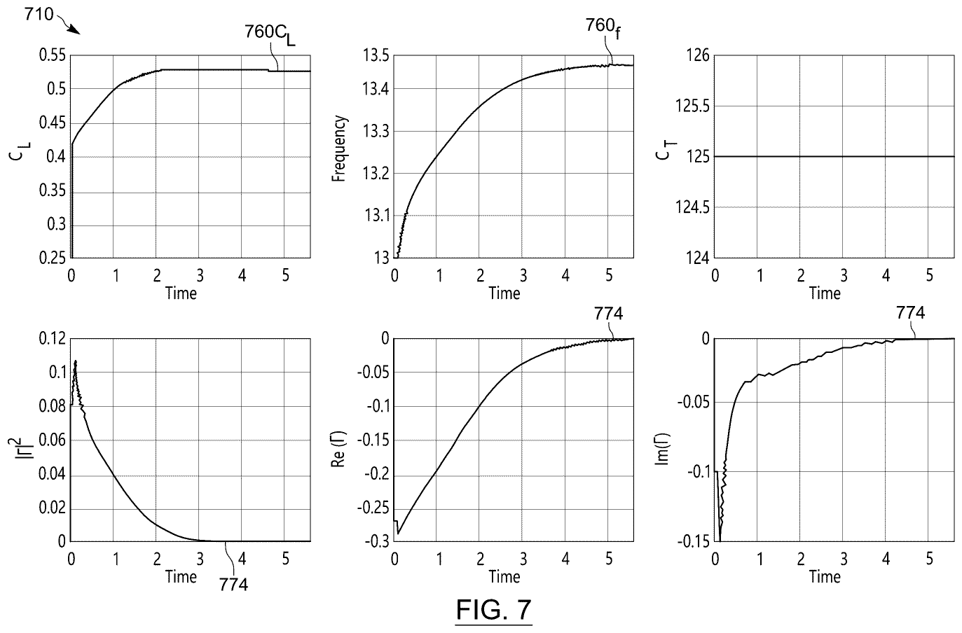

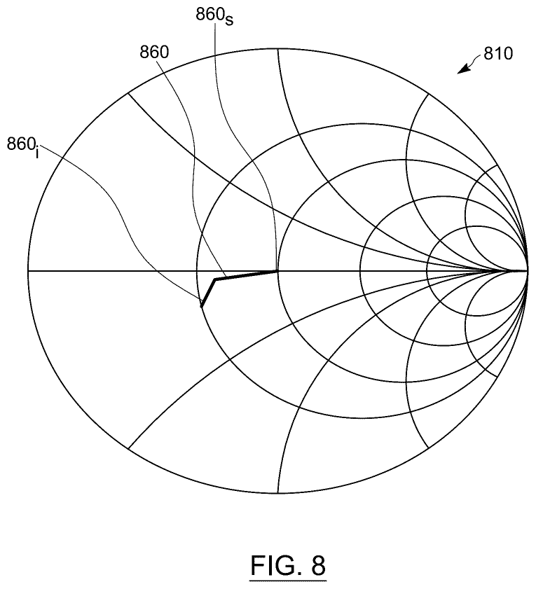

FIG. 7 shows time series plots 710 of the square of the magnitude and real and imaginary parts of the reflection coefficient with respect to frequency f actuator, load capacitance C_{L} actuator, and the tune capacitance C_{T} actuator of FIGS. 5, 6A, and 6B for a successful tune. Tune capacitance C_{T} actuator of FIG. 7 is shown as having a fixed value over the time period of interest. As can be seen in FIG. 7, load capacitance C_{L} reaches a solution automatically at position 760_{CL} and frequency f reaches a solution automatically at position 760_{f}. A solution is achieved when the error approaches zero for each of G_{mag}², Re(Γ), and Im(Γ) as shown at position 774. FIG. 8 shows a Smith chart 810 corresponding to FIG. 7 showing trajectory 860 of the reflection coefficient Γ from an initial condition 860ᵢ to an end or solution 860ₛ.

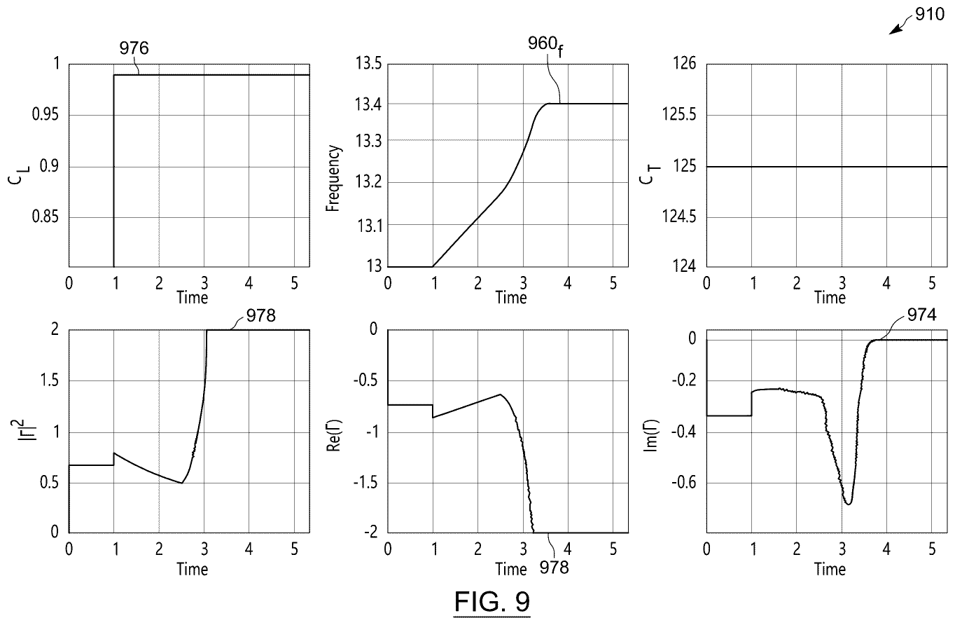

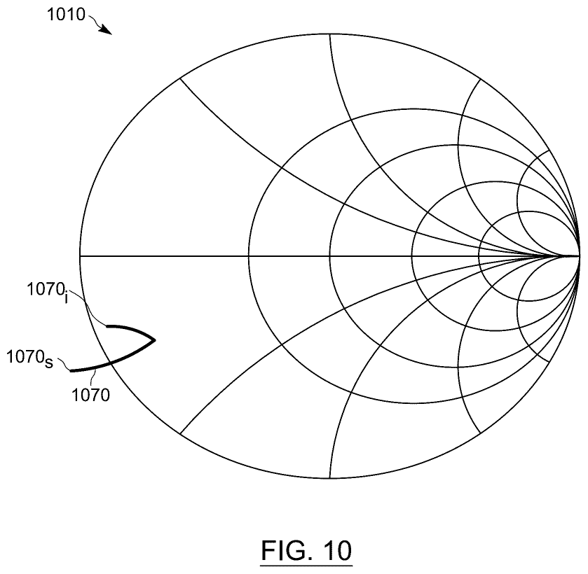

FIG. 9 shows time series plots 910 of the square of the magnitude and real and imaginary parts of the reflection coefficient with respect to frequency f actuator, load capacitance C_{L} actuator, and the tune capacitance C_{T} actuator of FIGS. 5, 6A, and 6B for a tune that fails to reach a solution using prior, conventional methods. As can be seen in FIG. 9, load capacitance C_{L} saturates in the wrong direction at position 976 which causes real part of the reflection coefficient Re(Γ) to diverge from a solution as shown at position 978 for the square of the magnitude of the reflection coefficient G_{mag}² and the real part of the reflection coefficient Re(Γ). The frequency reaches a solution at position 960f, and the error approaches zero for the imaginary part of the reflection coefficient Im(Γ) as shown at position 974. FIG. 10 shows a Smith chart 1010 corresponding to FIG. 9 showing a trajectory 1070 of the reflection coefficient Γ from an initial condition 1070ᵢ to an end 1070ₛ. Because end 1070s is outside the boundaries of Smith chart 1010, no solution can be found under the conventional servo tuning approaches to tuning for this initial condition.

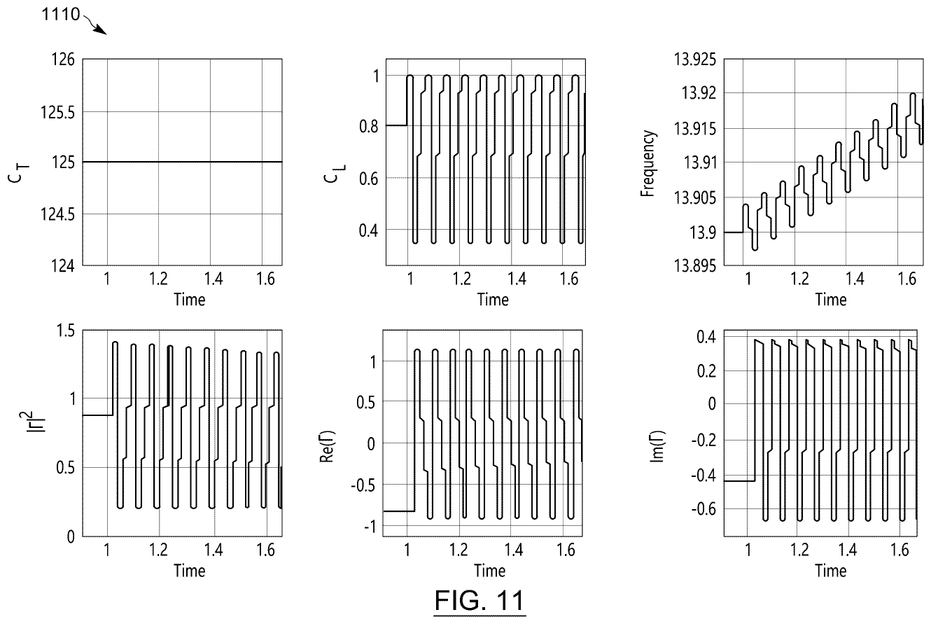

FIG. 11 shows time series plots 1110 of the square of the magnitude, real and imaginary of the reflection coefficient with respect to frequency f actuator, the load capacitance C_{L} actuator, and tune capacitance C_{T} actuator for a tune using conventional approaches that causes oscillations of the actuators. In the time series plots 1110 of FIG. 11, the separate servo tuning loops result in sustained oscillations which inhibit maintaining a solution.

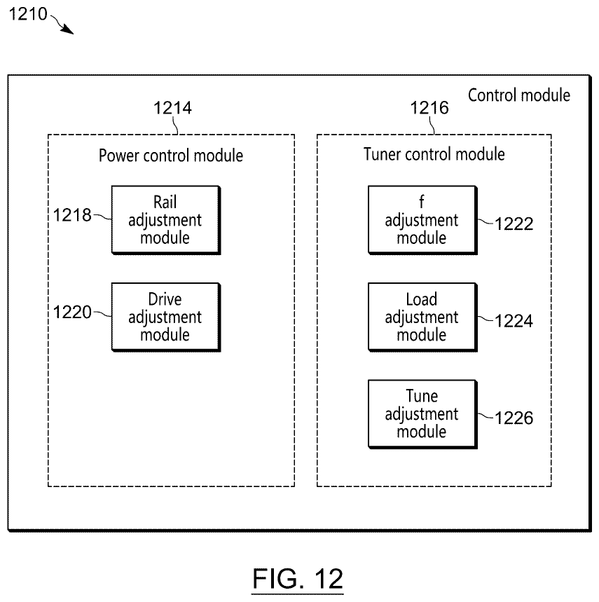

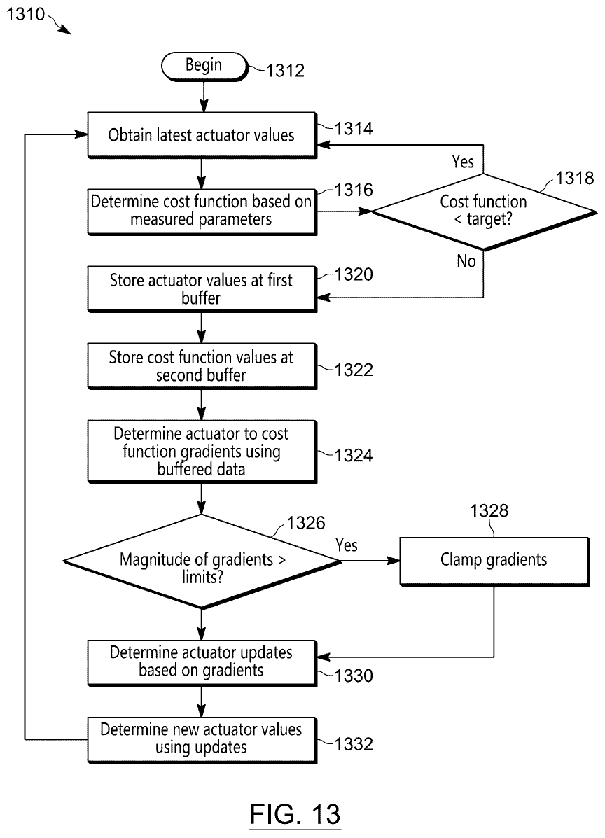

FIG. 12 incorporates various components of FIGS. 1 and 4. Control module 1210 may include power control module section 1214 and tuner control module section 1216. Power control module section 1214 includes rail adjustment module 1218 and drive adjustment module 1220. Tuner control module section 1216 includes frequency adjustment module 1222, load adjustment module 1224, and to tune adjustment module 1226. In various configurations, control module 1210 includes one or a plurality of processors that execute code associated with the module sections or modules 1210, 1214, 1216, 1218, 1220, 1222, 1224, 1226. Operation of the module sections or modules 1210, 1214, 1216, 1218, 1220, 1222, 1224, 1226 is described below with respect to one or more FIGS. 13-17.

For further defined structure of controllers 120a, 120b, and 120′ of FIGS. 1 and 4, see the below provided flow chart of FIGS. 13-17 and the below provided definition for the term “module”. The systems disclosed herein may be operated using numerous methods, examples, and various control system methods of which are illustrated in FIGS. 1 and 4. Although the following operations are primarily described with respect to the implementations of FIGS. 1 and 4, the operations may be easily modified to apply to other implementations of the present disclosure. The operations may be iteratively performed. Although the following operations are shown and primarily described as being performed sequentially, one or more of the following operations may be performed while one or more of the other operations are being performed.

Various configurations may be used to implement the MIMO control described herein to receive a plurality of inputs and determine a plurality of outputs for impedance tuning. In the various configurations, a plurality of control actuators is varied in order to correspondingly vary a plurality of parameters or a cost function determined in accordance with a plurality of parameters. The parameters may include a plurality of forward power, reverse power, current, voltage, power amplifier dissipation, power controller stability margins, estimated plasma stability, impedance Z, reflection coefficient Γ, one or more of the real or imaginary parts of the reflection coefficient Γ, or G_{mag}². The cost function may be determined in accordance with a plurality of the parameters and may be weighted or unweighted. In various configurations, the cost function may include impedance Z, reflection coefficient Γ, one or more of the real or imaginary parts of the reflection coefficient Γ, or G_{mag}². Further, in various configurations, the various parameters and cost functions can be combined to yield a single cost output or multiple cost outputs used to effect control. The cost function results in a value determining in accordance with a plurality of the parameters. In various configurations, control actuators may be determined by introducing perturbation signals into the output of source generator 112a, 412 and employing an extremum seeking control approach to adjust control actuators to minimize or maximize a parameter or cost varying in response to the perturbation. An extremum seeking control actuator tuning approach is described in U.S. Pat. No. 10,741,363, issued Aug. 11, 2020, entitled Extremum Seeking Control Apparatus and Method for Automatic Frequency Tuning for RF Impedance Matching, assigned to the assignee of the present application, and incorporated by reference herein.

FIG. 13 shows a flow chart of control system 1310 for performing MIMO-based impedance control for the power delivery systems of FIGS. 1 and 4. In the flow chart of FIG. 13, control system 1310 determines adjustments of actuators based on a gradient of a cost function. The control actuator tuning approach is described in greater detail in U.S. patent application Ser. No. 17/903,749, filed Sep. 8, 2022, entitled Extremum-Seeking Control Apparatuses and Methods for Automatic Frequency Tuning, assigned to the assignee of the present application, and incorporated by reference herein.

Control begins at 1312 and proceeds to 1314 where the latest actuator values are obtained. Control proceeds to 1316 where a cost function is determined based on one or more parameters. The cost function is compared to a target at 1318. If the cost function is less than the target, indicating that the cost function has not sufficiently changed to necessitate adjusting the actuators, control proceeds to 1314 where the latest actuator values are obtained. If the cost function exceeds the target, control proceeds to 1320 where one or more latest actuator values are stored in a first buffer. Control proceeds to 1322 where one or more cost function values are stored in a second buffer. At 1324, one or more actuator cost function gradients are determined using data stored in the respective first buffer and second buffer. Control then proceeds to 1326 where the magnitude of the one or more cost function gradients are compared to respective limits. If the magnitude of the respective one or more gradients exceeds the respective limits, control proceeds to 1328 which clamps the gradients in order to limit the magnitude of change in the one or more gradients for that iteration. If the magnitude of the one or more gradients are less than the respective limits, control proceeds to 1330 were the actuator updates are determined based on the one or more gradients. Control proceeds to 1332 were new actuator values are determined based on the actuator updates determined at 1330. Control proceeds to 1314 where the latest actuator values are obtained.

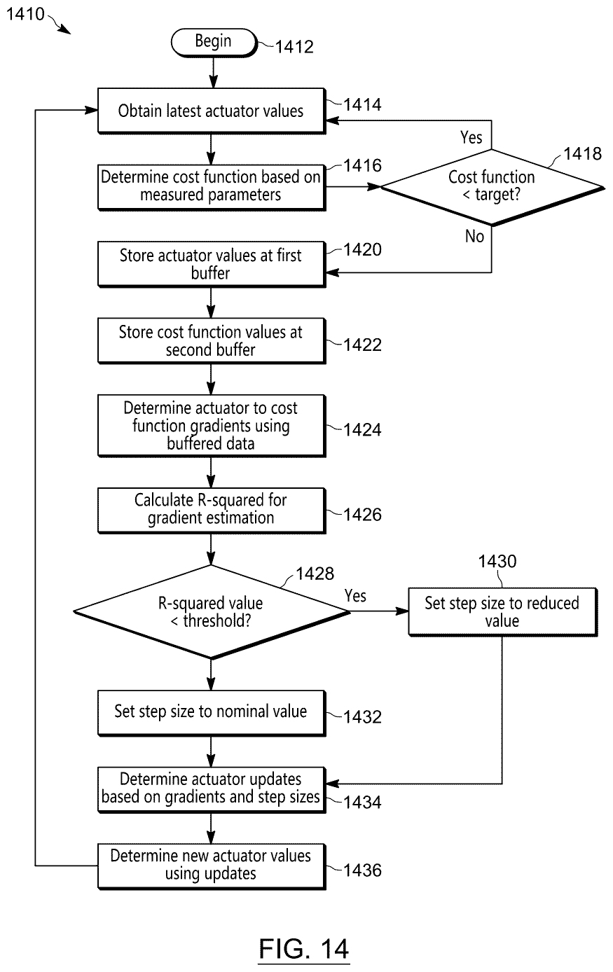

FIG. 14 shows a flow chart of control system 1410 for performing MIMO-based impedance control for the power delivery systems of FIGS. 1 and 4. In the flow chart of FIG. 14, control system 1410 determines adjustments of actuators based on a gradient of a cost function, similarly to FIG. 13, and uses at least two different step sizes to adjust the actuators. Control begins at 1412 and proceeds to 1414 where the latest actuator values are obtained. Control proceeds to 1416 where a cost function is determined based on one or more parameters. The cost function is compared to a target at 1418. If the cost function is less than the target, indicating that the cost function has not sufficiently changed to necessitate adjusting the actuators, control proceeds to 1414 where the latest actuator values are obtained. If the cost function exceeds the target, control proceeds to 1420 where one or more latest actuator values are stored in a first buffer. Control proceeds to 1422 where one or more cost function values are stored in a second buffer. At 1424, one or more actuator cost function gradients are determined using data stored in the respective first buffer and second buffer. Control proceeds to 1426 where R-squared, or the coefficient of determination, for the gradient estimate is determined, indicating closeness of the fit of the gradient estimate to the data.

At 1428, the R-squared values are compared to a threshold. If the R-squared values are equal to or exceed the threshold control proceeds to 1432 where the step size is set to a nominal value. If the R-squared values are less than the threshold, indicating that a strong second-order polynomial trend was not found in the buffered actuator and cost data, control proceeds to 1430 where the step size is set to a reduced value. With a reduced value step size, the actuator updates occur at a lower rate than that resulting from a step size of nominal value. Control proceeds to 1434 where the actuator updates are based on the gradients and the selected step size. Control proceeds to 1436 were new actuator values are determined based on the actuator updates determined at 1434. Control proceeds to 1414 where the latest actuator values are obtained. One skilled in the art will recognize that while FIG. 14 provides for two different step sizes, multiple step sizes may be selected in accordance with multiple thresholds of R-squared. In various configurations, the step size may decrease as R-squared decreases and increase as R-squared increases. In addition, while FIG. 14 provides for two different step sizes, continuous variation may also be used in accordance with the present disclosure, such as, for example, by multiplying the calculated step size by R-squared.

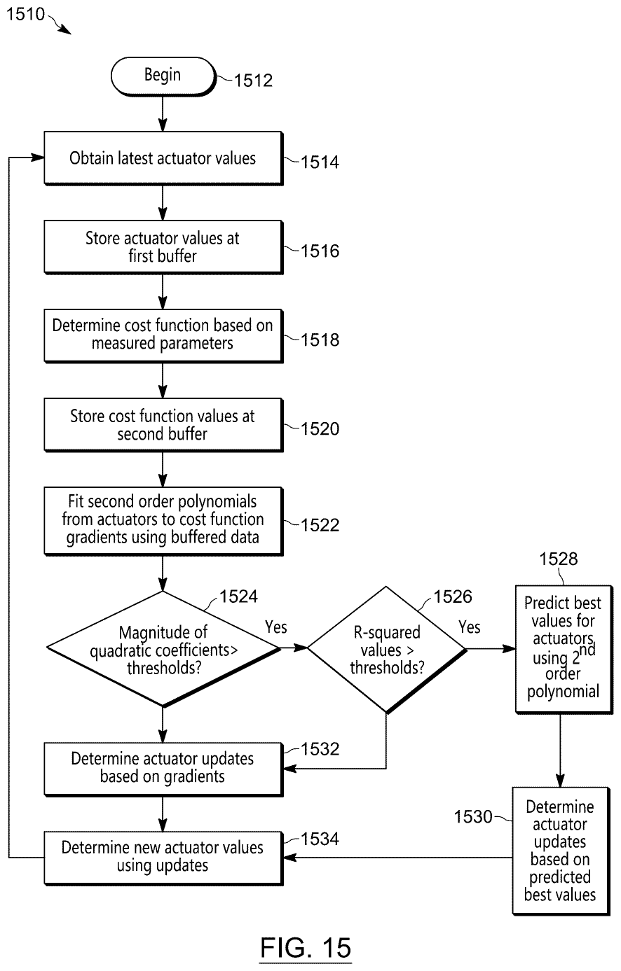

FIG. 15 shows a flow chart of control system 1510 for performing MIMO-based impedance control for the power delivery systems of FIGS. 1 and 4. In the flow chart of FIG. 15, control system applies a gradient descent approach to fit the gradient to a second order polynomial, rather than a linear fit. Control begins at 1512 and proceeds to 1514 where the latest actuator values are obtained. Control proceeds to 1516 where one or more of the latest actuator values are stored in a first buffer. Control proceeds to 1518 where a cost function is determined based on one or more measured parameters. Control proceeds to 1520 where one or more of the cost function values are stored in a second buffer. Control then proceeds to 1522 where one or more second order polynomials are fitted from the one or more actuators to one or more cost function gradients using the buffered data. Control proceeds to 1524 which compares the magnitude of one or more quadratic coefficients to one or more respective coefficient thresholds. If the one or more quadratic coefficients exceed the respective coefficient thresholds, control proceeds to 1526 where one or more R-squared values, the coefficient of determination, are compared to respective R-squared thresholds. If the one or more R-squared values exceed respective R-squared thresholds, control proceeds to 1528. At 1528, one or more best fit values for respective one or more actuators are predicted using a second order polynomial. Control proceeds to 1530 where one or more actuator updates are determined based on the one or more predicted best fit values. Control proceeds to 1534 where one or more new actuator values are determined based on the one or more actuator updates. Control then proceeds to 1514.

Retuning to 1524 and 1526, if the magnitudes of the one or more quadratic coefficients are less than the one or more quadratic thresholds, or the one or more R-squared values are less than the respective one or more R-squared thresholds, control proceeds to 1532 where one or more actuator updates are determined based on the linear gradient estimates. Thus, control proceeds to 1532 from 1524 when the quadratic coefficients are less than one or more respective thresholds, indicating that there is little curvature in the gradient data. In other words, the gradient estimates from the local buffered actuator and cost data are dominant linearly and the second-order (quadradic) information is not used to estimate where the solution at zero gradient is likely to be found. Instead, the actuator updates are calculated based on linear gradient estimates. Control proceeds to 1532 from 1526 when the R-squared value is less than a threshold, indicating that the strong second-order polynomial trend was not found in the buffered actuator and cost data. In this case, the second-order (quadratic) information is not used to estimate where the solution at zero gradient is likely to be found. Instead, the actuator updates are calculated based on linear gradient estimates.

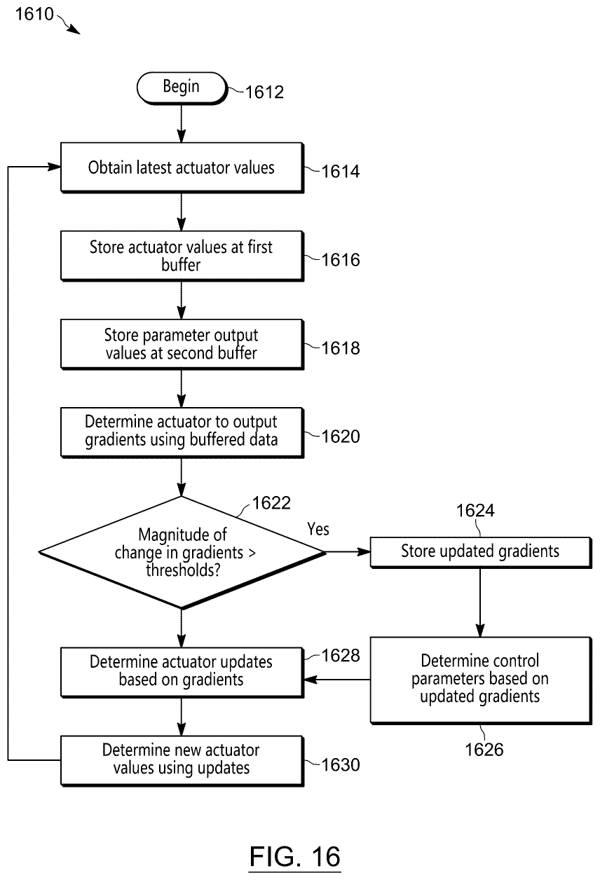

FIG. 16 shows a flow chart of control system 1610 for performing MIMO-based impedance control for the power delivery systems of FIGS. 1 and 4. In the flow chart of FIG. 16, control system 1610 adjusts one or more control parameters that determine adjustments of actuators in accordance with the principals of the present disclosure. Control begins at 1612 and proceeds to 1614 where the latest actuator values are obtained. Control proceeds to 1616 where the one or more of the latest actuator values are stored in a first buffer. Control proceeds to 1618 where one or more parameter output values are stored in a second buffer. Control proceeds to 1620 where data in the first and second buffers is used to determine actuator to output gradients. Control proceeds to 1622 where the magnitude of one or more of the gradients is compared to respective one or more thresholds. If the magnitude of the one or more gradients is greater than the respective one or more thresholds, control proceeds to 1624 where the updated gradients are stored. Control proceeds to 1626 which determines updated control parameters based on the updated gradients. In various configurations, the control parameters can include, but are not limited to, learning rate, feedback gains, stimulus amplitude, stimulus type, stimulus parameters (such as frequency content), cost function weights, or other control parameters. Control proceeds to 1628 where one or more actuator updates are determined based on the one or more gradients. Returning to 1622, if the magnitude of the one or more gradients is less than the respective one or more thresholds, control proceeds to 1628, which operates as described above. Control proceeds to 1630 where one or more new actuator values are determined based on the one or more actuator updates. Control proceeds to 1614.

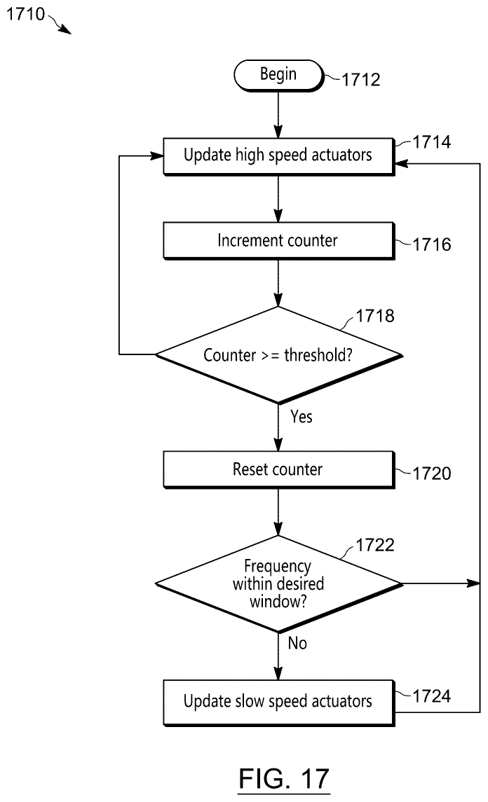

FIG. 17 shows a flow chart of control system 1710 for performing MIMO-based impedance control for the power delivery systems of FIGS. 1 and 4. In the flow chart of FIG. 17, a control system 1710 is configured for a power delivery system having actuators that operate at different speeds and are sampled at different sampling rates in accordance with the principals of the present disclosure. Control begins at 1712 and proceeds to 1714. At 1714, one or more high-speed actuators are updated, and control proceeds to 1716 where a counter is incremented. At 1718, the counter is compared to a counter threshold. If the counter is less than the counter threshold, control returns to 1714 to update the one or more high-speed actuators. Returning to 1718, if the counter is equal to or exceeds the counter threshold, control proceeds to 1720 where the counter is reset. Control proceeds to 1722 where it is determined if the frequency is within a desired window. If the frequency is within a desired window, control proceeds to 1714, where the one or more high-speed actuators are updated.

The items of 1714, 1716, 1718, 1720 are directed to control of a high-speed actuator, such as one or more of frequency f or tune capacitance C_{T}. Blocks 1714, 1716, 1718 are directed to taking multiple samples of high-speed actuators. Returning to 1722, if frequency f is outside of a desired window, control proceeds to 1724 where one or more of the slow speed actuators are updated. By way of nonlimiting example, a slow speed actuator could be load capacitance C_{L}. FIG. 17, allows for the control of both one or more high-speed actuators sampled at a high sampling rate and one or more low-speed actuators sampled at a lower sampling rate.

With further reference to FIG. 17, in a typical power delivery system, tune capacitance C_{T} (such as 418_{T} of FIG. 4) actuator is implemented as a conventional vacuum variable capacitor (VVC). Accordingly tune capacitance C_{T} 418_{T} actuator adjusts orders of magnitude more slowly than high speed actuators, such as frequency f actuator and load capacitance C_{L} (such as 418_{L} of FIG. 4) actuator. Using both frequency f actuator and load capacitance C_{L} 418_{L} actuator provides high speed tuning over a small reactance range for pulsed operation enabling a wider tuning range on longer time scales. Such a longer time scale may be, by way of nonlimiting example, a recipe step change. Fast actuators frequency f and load capacitance C_{L} 418_{L} typically tune within microseconds, and slower tune capacitance C_{T} 418_{T} actuator drives the frequency actuator to a target, such as 13.56 MHz, over tens of milliseconds. In various configurations, the controller for the tune capacitance C_{T} 418_{T} actuator can be a simple servo controller or the extremum seeking control type actuator used for the fast actuators. An example of such a hybrid control actuator tuning approach is described in greater detail in U.S. patent application Ser. No. 17/873,624, filed Jul. 26, 2022, entitled Hybrid High-Power And Broadband Variable Impedance Modules, assigned to the assignee of the present application, and incorporated by reference herein. FIG. 17 shows a MIMO-based impedance control for the power delivery systems of FIGS. 1 and 4 where the actuators implement a hybrid tuning configuration.

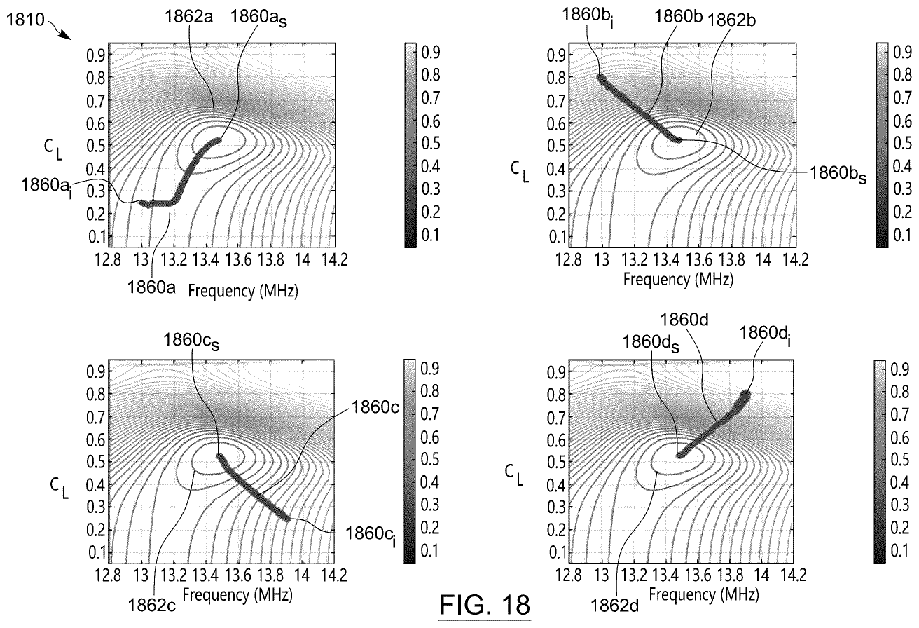

FIG. 18 shows contour plots 1810 of cost function G_{mag}² varying with respect to frequency f actuator and load capacitance C_{L} actuator and shows various tuning trajectories 1860. Each tuning trajectory 1860 originates in a respective quadrant of the contour plots and is determined using an extremum seeking control tuning approach such as described in U.S. Pat. No. 10,741,363, entitled Extremum Seeking Control Apparatus and Method for Automatic Frequency Tuning for RF Impedance Matching or U.S. patent application Ser. No. 17/903,749, entitled Extremum-Seeking Control Apparatuses and Methods for Automatic Frequency Tuning, both referenced above. Each actuator frequency f and load capacitance C_{L} seeks to minimize the overall cost function G_{mag}², rather than optimizing separate targets via individual servo loops, to reduce conflicts between each actuator. Each trajectory 1860a, 1860b, 1860c, 1860d, is initiated in a respective lower left, upper left, lower right, upper right quadrant of the contour plot, as shown at 1860aᵢ (G_{mag}²≅0.095), 1860bᵢ (G_{mag}²≅0.693), 1860cᵢ (G_{mag}²≅0.233), 1860dᵢ (G_{mag}²≅0.0877). In each contour plot, the tuning trajectory moves to a respective region 1862a, 1862b, 1862c, 1862d of relatively low reflection coefficient of approaching approximately 0 (G_{mag}²≅0.049) and terminates at a respective solution 1860aₛ, 1860bₛ, 1860cₛ, 1860dₛ.

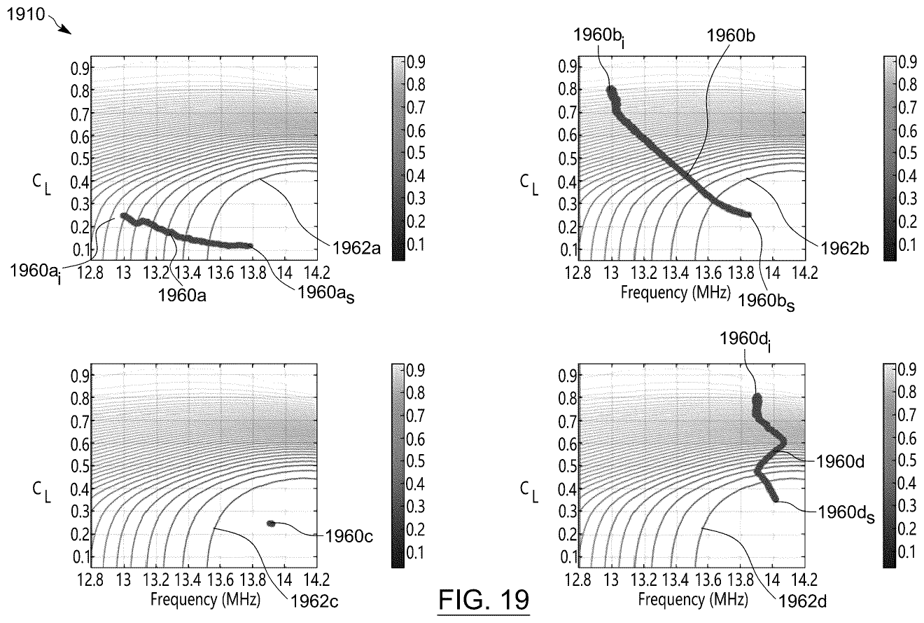

FIG. 19 shows contour plots 1910 of cost function G_{mag}² varying with respect to frequency f actuator and load capacitance C_{L} actuator and shows various tuning trajectories 1960. Each tuning trajectory 1960 originates in a respective quadrant of the contour plots and is determined using an extremum seeking control tuning approach such as referenced with respect to FIG. 18. Each actuator frequency f and load capacitance C_{L} seeks to minimize the cost function G_{mag}² to reduce conflicts between each actuator. Each trajectory 1960a, 1960b, 1960c, 1960d, is initiated in a respective lower left, upper left, lower right, upper right quadrant of the contour plot, as shown at starting or initial conditions 1960aᵢ (G_{mag}²≅0.140), 1960bᵢ (G_{mag}²≅0.856), 1960dᵢ (G_{mag}²≅0.856). The tuning trajectory moves to a respective region 1962a, 1962b, 1962c, 1962d of relatively low reflection coefficient approaching approximately 0 (G_{mag}²≅0.046) and terminates at solutions 1960aₛ, 1960bₛ, 1960dₛ. The initial condition and solution for trajectory 1960c are sufficiently close that only trajectory 1960c is shown.

As shown in FIG. 19, a wide range of slopes exist in the actuator space. For example, frequency f actuator has little effect on cost function G_{mag}² when load capacitance C_{L} actuator is high. A conventional independent servo frequency f controller would be challenged tuning this condition until the duty cycle was reduced. The extremum MIMO-based seeking control tuning approach achieves a solution from all four initial conditions as shown in FIG. 19.

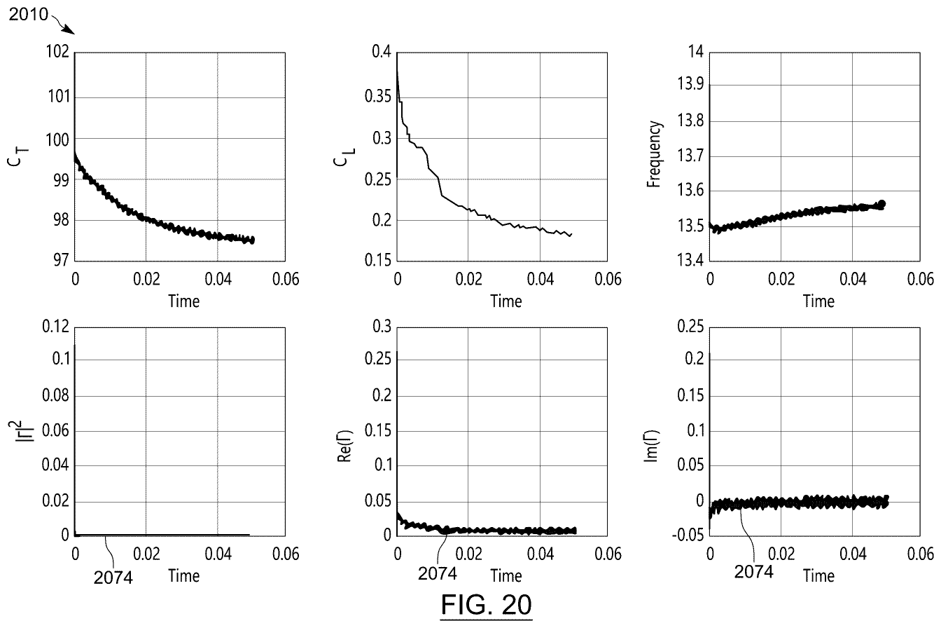

FIG. 20 shows time series plots 2010 of the G_{mag}², Re(Γ), and Im(Γ) with respect to frequency f actuator, load capacitance C_{L} actuator, the tune capacitance C_{T} actuator using a tuning approach of FIG. 17. As can be seen in FIG. 20, load capacitance C_{L} reaches a solution at position 2074 in minimal time of approximately 50 msec. At this time, the frequency actuator is at the target frequency and the reflection coefficient magnitude is minimized.

The various configurations described herein may provide one or more of the following benefits, including improved robustness over conventional servo tuning systems that control each actuator in independent tuning loops. The various configurations described herein may provide improved stability over conventional servo tuning systems that control each actuator in independent tuning loops. The various configurations described herein may provide faster convergence to an optimal solution because actuators are updated in the same loop, which reduces conflicts, such as may occur in conventional servo tuning systems that control each actuator in independent tuning loops. The various configurations described herein may facilitate optimization and configuration for a given plasma application because there are fewer parameters to adjust, as compared to conventional servo tuning systems that control each actuator in independent tuning loops. The various configurations described herein facilitate maintaining the frequency of operation of the generator at a customer-specified target in a steady state.

### Conclusion

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. In the written description and claims, one or more steps within a method may be executed in a different order (or concurrently) without altering the principles of the present disclosure. Similarly, one or more instructions stored in a non-transitory computer-readable medium may be executed in a different order (or concurrently) without altering the principles of the present disclosure. Unless indicated otherwise, numbering or other labeling of instructions or method steps is done for convenient reference, not to indicate a fixed order.

Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements.

The phrase “at least one of A, B, and C” should be construed to mean a logical (A OR B OR C), using a non-exclusive logical OR, and should not be construed to mean “at least one of A, at least one of B, and at least one of C.” The term “set” does not necessarily exclude the empty set—in other words, in some circumstances a “set” may have zero elements. The term “non-empty set” may be used to indicate exclusion of the empty set—in other words, a non-empty set will always have one or more elements. The term “subset” does not necessarily require a proper subset. In other words, a “subset” of a first set may be coextensive with (equal to) the first set. Further, the term “subset” does not necessarily exclude the empty set—in some circumstances a “subset” may have zero elements.

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” can be replaced with the term “controller” or the term “circuit.” In this application, the term “controller” can be replaced with the term “module.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); processor hardware (shared, dedicated, or group) that executes code; memory hardware (shared, dedicated, or group) that stores code executed by the processor hardware; other suitable hardware components that provide the described functionality; or a combination of some or all of the above, such as in a system-on-chip.

The module may include one or more interface circuits. In some examples, the interface circuit(s) may implement wired or wireless interfaces that connect to a local area network (LAN) or a wireless personal area network (WPAN). Examples of a LAN are Institute of Electrical and Electronics Engineers (IEEE) Standard 802.11-2020 (also known aₛ the WIFI wireless networking standard) and IEEE Standard 802.3-2018 (also known as the ETHERNET wired networking standard). Examples of a WPAN are IEEE Standard 802.15.4 (including the ZIGBEE standard from the ZigBee Alliance) and, from the Bluetooth Special Interest Group (SIG), the BLUETOOTH wireless networking standard (including Core Specification versions 3.0, 4.0, 4.1, 4.2, 5.0, and 5.1 from the Bluetooth SIG).

The module may communicate with other modules using the interface circuit(s). Although the module may be depicted in the present disclosure as logically communicating directly with other modules, in various implementations the module may actually communicate via a communications system. The communications system includes physical and/or virtual networking equipment such as hubs, switches, routers, and gateways. In some implementations, the communications system connects to or traverses a wide area network (WAN) such as the Internet. For example, the communications system may include multiple LANs connected to each other over the Internet or point-to-point leased lines using technologies including Multiprotocol Label Switching (MPLS) and virtual private networks (VPNs).

In various implementations, the functionality of the module may be distributed among multiple modules that are connected via the communications system. For example, multiple modules may implement the same functionality distributed by a load balancing system. In a further example, the functionality of the module may be split between a server (also known as remote, or cloud) module and a client (or, user) module. For example, the client module may include a native or web application executing on a client device and in network communication with the server module.

Some or all hardware features of a module may be defined using a language for hardware description, such as IEEE Standard 1364-2005 (commonly called “Verilog”) and IEEE Standard 1076-2008 (commonly called “VHDL”). The hardware description language may be used to manufacture and/or program a hardware circuit. In some implementations, some or all features of a module may be defined by a language, such as IEEE 1666-2005 (commonly called “SystemC”), that encompasses both code, as described below, and hardware description.

The term code, as used above, may include software, firmware, and/or microcode, and may refer to programs, routines, functions, classes, data structures, and/or objects. Shared processor hardware encompasses a single microprocessor that executes some or all code from multiple modules. Group processor hardware encompasses a microprocessor that, in combination with additional microprocessors, executes some or all code from one or more modules. References to multiple microprocessors encompass multiple microprocessors on discrete dies, multiple microprocessors on a single die, multiple cores of a single microprocessor, multiple threads of a single microprocessor, or a combination of the above.

The memory hardware may also store data together with or separate from the code. Shared memory hardware encompasses a single memory device that stores some or all code from multiple modules. One example of shared memory hardware may be level 1 cache on or near a microprocessor die, which may store code from multiple modules. Another example of shared memory hardware may be persistent storage, such as a solid state drive (SSD), which may store code from multiple modules. Group memory hardware encompasses a memory device that, in combination with other memory devices, stores some or all code from one or more modules. One example of group memory hardware is a storage area network (SAN), which may store code of a particular module across multiple physical devices. Another example of group memory hardware is random access memory of each of a set of servers that, in combination, store code of a particular module.

The term memory hardware is a subset of the term computer-readable medium. The term computer-readable medium, as used herein, does not encompass transitory electrical or electromagnetic signals propagating through a medium (such as on a carrier wave); the term computer-readable medium is therefore considered tangible and non-transitory. Non-limiting examples of a non-transitory computer-readable medium are nonvolatile memory devices (such as a flash memory device, an erasable programmable read-only memory device, or a mask read-only memory device), volatile memory devices (such as a static random access memory device or a dynamic random access memory device), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. Such apparatuses and methods may be described as computerized apparatuses and computerized methods. The functional blocks and flowchart elements described above serve as software specifications, which can be translated into the computer programs by the routine work of a skilled technician or programmer.

The computer programs include processor-executable instructions that are stored on at least one non-transitory computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation), (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Swift, Haskell, Go, SQL, R, Lisp, Java®, Fortran, Perl, Pascal, Curl, OCaml, JavaScript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

What is claimed is:

1. A controller for a power generator comprising:
a power controller configured to generate a plurality of control signals to vary a respective plurality of actuators controlling a power output by the power generator to a load,
wherein the plurality of control signals is determined in accordance with a cost function that varies based on a plurality of parameters of the power output by the power generator.

2. The controller of claim 1 wherein the plurality of control signals is controlled in accordance with one of minimizing or maximizing the cost function.

3. The controller of claim 1 wherein the plurality of parameters includes forward power, reverse power, current, voltage, power amplifier dissipation, power controller stability margins, estimated plasma stability, impedance, reflection coefficient, real or imaginary parts of the reflection coefficient, or magnitude of the square of the reflection coefficient.

4. The controller of claim 1 wherein the cost function includes one of impedance, reflection coefficient, one or more of real or imaginary parts of the reflection coefficient, or magnitude of the square of the reflection coefficient.

5. The controller of claim 1 wherein the plurality of actuators includes at least a plurality of frequency, load capacitance, and tune capacitance.

6. The controller of claim 1 wherein the plurality of actuators includes at least a plurality of frequency, load capacitance, tune capacitance, rail voltage, and drive voltage.

7. The controller of claim 1 wherein the power controller is configured to apply an extremum seeking control approach to generate the plurality of control signals.

8. The controller of claim 7 wherein the power controller is configured to at least one of:
select a step size from a plurality of step sizes for at least one of the plurality of control signals and update the at least one of the plurality of control signals in accordance with the selected step size;
determine a gradient of the cost function and determine updates to the plurality of control signals based on the gradient; or
determine a best fit of a polynomial and determine updates to the plurality of control signals based on the polynomial.

9. The controller of claim 1 wherein at least one of the plurality of control signals is updated at a first rate and an other of the plurality of control signals is updated at a second rate, wherein the first rate is faster than the second rate, and a frequency and load capacitance is updated at the first rate, and a tune capacitance is updated at the second rate.

10. A power generator system comprising:
a power source, the power source generating an output power communicated to a load;
a matching network between the power source and the load, the matching network receiving the output power and providing an impedance match between the power source and the load, wherein the matching network includes a load capacitance and a tune capacitance; and
a controller coupled to the power source and the matching network, the power controller configured to generate a plurality of control signals communicated to the power source and the matching network to vary a respective plurality of actuators controlling the power communicated to a load,
wherein the plurality of actuators includes frequency of the power source, load capacitance of the matching network, and tune capacitance of the matching network, and plurality of control signal control the respective plurality of actuators, and
wherein the plurality of control signals is determined in accordance with a cost function that varies based on a plurality of parameters of the power output by the power generator.

11. The power generator system of claim 10 wherein the plurality of control signals is controlled in accordance with one of minimizing or maximizing the cost function.

12. The power generator system of claim 10 wherein the plurality of parameters includes forward power, reverse power, current, voltage, power amplifier dissipation, power controller stability margins, estimated plasma stability, impedance, reflection coefficient, real or imaginary parts of the reflection coefficient, or magnitude of the square of the reflection coefficient.

13. The power generator system of claim 10 wherein the cost function includes one of impedance, reflection coefficient, one or more of real or imaginary parts of the reflection coefficient, or magnitude of the square of the reflection coefficient.

14. The power generator system of claim 10 wherein the plurality of actuators further includes at least one of rail voltage and drive voltage.

15. The power generator system of claim 10 wherein the power controller is configured to apply an extremum seeking control approach to generate the plurality of control signals.

16. The power generator system of claim 15 wherein the power controller is configured to at least one of:
select a step size from a plurality of step sizes for at least one of the plurality of control signals and update the at least one of the plurality of control signals in accordance with the selected step size;
determine a gradient of the cost function and communicate updates to the plurality of control signals based on the gradient; or
determine a best fit of a polynomial and communicate updates to the plurality of control signals based on the polynomial.

17. The power generator system of claim 10 wherein at least one of the plurality of control signals is updated at a first rate and an other of the plurality of control signals is updated at a second rate, wherein the first rate is faster than the second rate, and the frequency and load capacitance is updated at the first rate, and the tune capacitance is updated at the second rate.

18. A non-transitory computer-readable medium storing instructions, the instructions comprising:
controlling a power source to generate an output power communicated to a load;
controlling a matching network between the power source and the load, the matching network receiving the output power and providing an impedance match between the power source and the load, wherein the matching network includes a load capacitance and a tune capacitance; and
generating a plurality of control signals to control the power source and the matching network to vary a respective plurality of actuators of the power source and the matching network,
wherein the plurality of actuators includes frequency of the power source, load capacitance of the matching network, and tune capacitance of the matching network, and
wherein the plurality of control signals is determined in accordance with a cost function that varies based on a plurality of parameters of the output power.

19. The non-transitory computer-readable medium storing instructions of claim 18 wherein the plurality of parameters includes forward power, reverse power, current, voltage, impedance, reflection coefficient, real or imaginary parts of the reflection coefficient, or magnitude of the square of the reflection coefficient.

20. The non-transitory computer-readable medium storing instructions of claim 18, the instructions further comprising at least one of:
selecting a step size from a plurality of step sizes for at least one of the plurality of control signals and update the at least one of the plurality of control signals in accordance with the selected step size;
determining a gradient of the cost function and communicate updates to the plurality of control signals based on the gradient; or
determining a best fit of a polynomial and communicate updates to the plurality of control signals based on the polynomial.
